(19) United States
(12) Patent Application Publication
(10) Pub. No.: US 2023/0387041 A1
(43) Pub. Date: Nov. 30, 2023

(54) SEMICONDUCTOR DEVICE AND SEMICONDUCTOR MODULE

(71) Applicant: ROHM CO., LTD., Kyoto-shi, Kyoto (JP)

(72) Inventor: Bungo TANAKA, Kyoto-shi, Kyoto (JP)

(73) Assignee: ROHM CO., LTD., Kyoto-shi, Kyoto (JP)

(21) Appl. No.: 18/029,105

(22) PCT Filed: Sep. 1, 2021
(86) PCT No.: PCT/JP2021/032178

§ 371 Date: Mar. 29, 2023

(30) Foreign Application Priority Data
Sep. 30, 2020 (JP) 2020-165411

(51) Int. Cl. H01L 23/64; H01F 17/00; H01F 27/40; H01F 27/32; H01F 27/29; H01L 23/495

(52) U.S. Cl. CPC H01L 23/645; H01F 17/0013; H01F 27/40; H01F 27/324; H01F 27/29; H01L 28/10; H01L 23/49562

(57) ABSTRACT

A semiconductor device includes a semiconductor chip that has a principal surface, a first conductive layer that is formed on the principal surface of the semiconductor chip and connected to a first potential, a second conductive layer that opposes the first conductive layer of the principal surface in a normal direction and is connected to a second potential higher than the first potential, an insulating layer that is formed between the first conductive layer and the second conductive layer, and a first pad that is formed in a region separated from a region that opposes the second conductive layer in a first direction in a plan view when the semiconductor chip is viewed in the normal direction and that is electrically connected to the first conductive layer.

### TECHNICAL FIELD

The present disclosure relates to a semiconductor device and a semiconductor module that includes the semiconductor device.

### BACKGROUND ART

For example, Patent Literature 1 discloses an integrated circuit that includes a power supply, a constant current source to which electricity is supplied by the power supply and which has an output terminal connected to an anode of a temperature-sensitive diode, a PWM comparator having a non-inverted input terminal and an inverted input terminal in which a voltage of the anode of the temperature-sensitive diode is applied to the non-inverted input terminal and a carrier signal (triangular wave signal) that is output by a carrier generating circuit is applied to the inverted input terminal, and a photo coupler, that is, an insulation means which is connected to an output terminal of the PWM comparator and transmits the signal, with a high-voltage system and a low-voltage system being insulated, from one side thereof to the other side thereof.

### PRIOR ART LITERATURE

### Patent Literature

Patent Literature 1: Japanese Patent Application Publication No. 2011-7580

### SUMMARY OF INVENTION

### Solution to Problem

A semiconductor device according to a preferred embodiment of the present disclosure includes a semiconductor chip that has a principal surface, a first conductive layer that is formed on the principal surface of the semiconductor chip and is connected to a first potential, a second conductive layer that opposes the first conductive layer of the principal surface in a normal direction and is connected to a second potential higher than the first potential, an insulating layer that is formed between the first conductive layer and the second conductive layer, and a first pad that is formed in a region separated from a region that opposes the second conductive layer in a first direction in a plan view when the semiconductor chip is viewed in the normal direction and that is electrically connected to the first conductive layer.

### BRIEF DESCRIPTION OF DRAWINGS

FIG. 1 is a plan view of a semiconductor module according to a preferred embodiment of the present disclosure.

FIG. 2 is a diagram for describing an operation of the semiconductor module shown in FIG. 1.

FIG. 3 is a voltage waveform diagram used in the description of FIG. 2.

FIG. 4 is a schematic plan view of a semiconductor device according to a preferred embodiment of the present disclosure.

FIG. 5 is a plan view which shows a layer in which a low potential coil is formed in the semiconductor device shown in FIG. 4.

FIG. 6 is a plan view which shows a layer in which a high potential coil is formed in the semiconductor device shown in FIG. 4.

FIG. 7 is an enlarged view of main parts of the high potential coil shown in FIG. 6.

FIG. 8 is an enlarged view of main parts of the high potential coil in FIG. 6.

FIG. 9 is a schematic sectional view of the semiconductor device shown in FIG. 4.

FIG. 10 is a diagram for describing the effects of the semiconductor device shown in FIG. 4.

FIG. 11 is a schematic plan view of a semiconductor device according to another preferred embodiment of the present disclosure.

FIG. 12 is a schematic plan view of a semiconductor device according to another preferred embodiment of the present disclosure.

FIG. 13 is a schematic plan view of a semiconductor device according to another preferred embodiment of the present disclosure.

FIG. 14 is a schematic plan view of a semiconductor device according to another preferred embodiment of the present disclosure.

FIG. 15 is a schematic sectional view of a semiconductor device according to another preferred embodiment of the present disclosure.

FIG. 16 is a schematic sectional view of a semiconductor device according to another preferred embodiment of the present disclosure.

FIG. 17 is a schematic sectional view of a semiconductor device according to another preferred embodiment of the present disclosure.

FIG. 18 is a schematic sectional view of a semiconductor device according to another preferred embodiment of the present disclosure.

FIG. 19 is a schematic sectional view of a semiconductor device according to another preferred embodiment of the present disclosure.

### DESCRIPTION OF EMBODIMENTS

### Preferred Embodiments of the Present Disclosure

First, preferred embodiments of the present disclosure will be given and described.

A semiconductor device according to a preferred embodiment of the present disclosure includes a semiconductor chip that has a principal surface, a first conductive layer that is formed on the principal surface of the semiconductor chip and is connected to a first potential, a second conductive layer that opposes the first conductive layer of the principal surface in a normal direction and is connected to a second potential higher than the first potential, an insulating layer that is formed between the first conductive layer and the second conductive layer, and a first pad that is formed in a region separated from a region that opposes the second conductive layer in a first direction in a plan view when the semiconductor chip is viewed in the normal direction and that is electrically connected to the first conductive layer.

According to this constitution, the first pad that is connected to a relatively low potential (first potential) is separated in the first direction in a plan view from a region that opposes the second conductive layer that is connected to a relatively high potential (second potential). Thereby, as compared with a case that the first pad is formed in this opposing region, it is possible to increase a creepage distance between the second conductive layer and the first pad. As a result, it is possible to suppress occurrence of a creeping discharge in a region between the second conductive layer and the first pad and, therefore, possible to suppress destruction and deterioration of the insulating layer between the second conductive layer and the first pad.

A semiconductor device according to a preferred embodiment of the present disclosure may include a second pad that is in alignment with respect to the second conductive layer in a second direction that intersects the first direction in a plan view, has a width smaller than a width of the second conductive layer in the first direction and is electrically connected to the second conductive layer.

In a semiconductor device according to a preferred embodiment of the present disclosure, the semiconductor chip may be formed in a quadrilateral shape that has a first corner portion and a second corner portion which are diagonal to each other as well as a third corner portion and a fourth corner portion which are diagonal to each other in a plan view, the second conductive layer may be provided one each such that the second conductive layer is close to the first corner portion, and the first pad may be provided such that the first pad is close to the second corner portion.

In a semiconductor device according to a preferred embodiment of the present disclosure, the semiconductor chip may be formed in a quadrilateral shape that has a first side and a second side which oppose each other as well as a third side and a fourth side which oppose each other in a plan view, the second conductive layer may be provided one each in the first side and the second side such that the second conductive layer is close thereto, and the first pad may be provided at least in one of the third side and the fourth side such that the first pad is close thereto in a region between the pair of second conductive layers that oppose each other.

In a semiconductor device according to a preferred embodiment of the present disclosure, the first conductive layer may include a first coil and the second conductive layer may include a second coil.

In a semiconductor device according to a preferred embodiment of the present disclosure, the second coil may be larger in thickness than the first coil.

In a semiconductor device according to a preferred embodiment of the present disclosure, the second coil may have a thickness larger than a pitch of the second coil.

In a semiconductor device according to a preferred embodiment of the present disclosure, the second coil may include a first portion that forms an outermost periphery of the second coil and has a first width, and a second portion that forms a coil portion further inside than the first portion and has a second width smaller than the first width.

In a semiconductor device according to a preferred embodiment of the present disclosure, a distance between the first portion and a portion of an outermost periphery of the second portion may be larger than a pitch of the second portion.

In a semiconductor device according to a preferred embodiment of the present disclosure, the first coil may be AlCu, and the second coil may be Cu.

A semiconductor device according to a preferred embodiment of the present disclosure may include a first conductive member that is connected to an inner end portion of the first coil, extends by crossing the first coil below the first coil and is electrically connected to the first pad.

In a semiconductor device according to a preferred embodiment of the present disclosure, the insulating layer may include an organic insulating layer.

In a semiconductor device according to a preferred embodiment of the present disclosure, the organic insulating layer may include at least one among a polyimide film, a phenol resin film and an epoxy resin film.

In a semiconductor device according to a preferred embodiment of the present disclosure, the insulating layer may include a laminated structure of a first inorganic insulating layer and a second inorganic insulating layer that is laminated on the first inorganic insulating layer.

In a semiconductor device according to a preferred embodiment of the present disclosure, the first inorganic insulating layer may include a silicon nitride film, and the second inorganic insulating layer may include a silicon oxide film.

A semiconductor module according to a preferred embodiment of the present disclosure includes a die pad, the semiconductor device that is installed on the die pad, a package main body that seals the die pad and the semiconductor device, and a lead terminal that is electrically connected to the semiconductor device and exposed from the package main body.

Where the semiconductor device includes a signal-transmitting insulating element for transmitting a signal between the first coil and the second coil in an insulation state, a semiconductor module according to a preferred embodiment of the present disclosure may further include a second semiconductor device that is electrically connected to the insulating element.

In a semiconductor module according to a preferred embodiment of the present disclosure, the second semiconductor device may include a control element that is electrically connected to one of the first coil and the second coil and a driving element that is electrically connected to the other of the first coil and the second coil.

### Detailed Description of Preferred Embodiments of the Present Disclosure

Next, the preferred embodiments of the present disclosure will be described in detail with reference to the attached drawings.

### First Preferred Embodiment

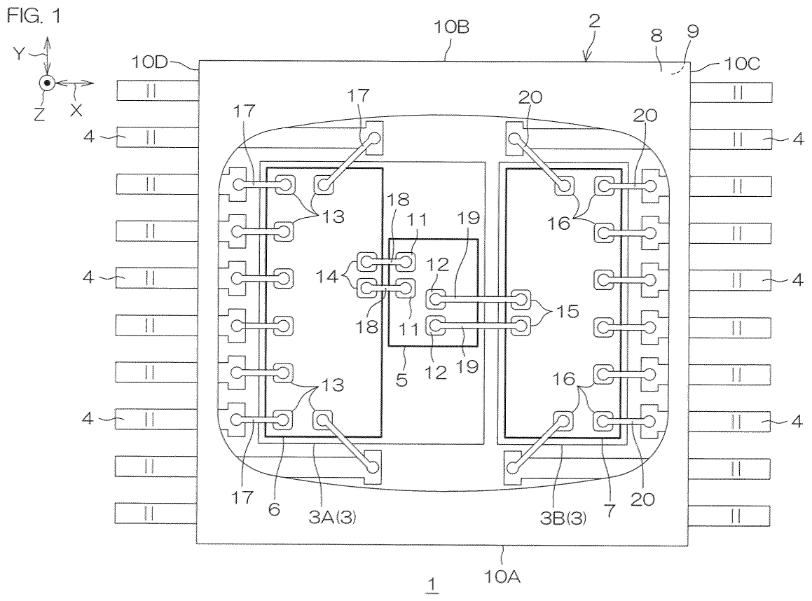

FIG. 1 is a plan view of a semiconductor module 1 according to a preferred embodiment of the present disclosure. In FIG. 1, a central portion of a package main body 2 is shown transparently for clarification of an internal structure.

With reference to FIG. 1, the semiconductor module 1 in this embodiment is constituted of an SOP (Small Outline Package). The semiconductor module 1 is not restricted to an SOP and may instead be constituted of a QFN (Quad for Non Lead Package), a DFP (Dual Flat Package), a DIP (Dual Inline Package), a QFP (Quad Flat Package), an SIP (Single Inline Package) or an SOJ (Small Outline J-leaded Package) or any of various packages related to these.

In this embodiment, the semiconductor module 1 is a composite type of module that includes a plurality of devices. The semiconductor module 1 includes the package main body 2, a plurality of die pads 3, a plurality of lead terminals 4, a semiconductor device 5 as an example of the insulating element of the present disclosure, a controller IC 6 as an example of the control element of the present disclosure, a driver IC 7 as an example of the driving element of the present disclosure, and a plurality of lead wires 17 to 20.

The semiconductor device 5 is a transformer chip that boosts and outputs an electrical signal that has been input. The controller IC 6 is an IC chip that drives and controls the semiconductor device 5. The driver IC 7 is an IC chip that generates an electrical signal in accordance with the electrical signal from the semiconductor device 5 to drive and control a load (for example, a switching device, etc.). The controller IC 6 is a low potential device with respect to the semiconductor device 5. The driver IC 7 is a high potential device with respect to the semiconductor device 5.

The package main body 2 contains a molded resin. The molded resin may include an epoxy resin. The package main body 2 is formed in a rectangular parallelepiped shape. The package main body 2 has a non-mounting surface 8 at one side, a mounting surface 9 at the other side, and side walls 10A to 10D connecting the non-mounting surface 8 and the mounting surface 9. The non-mounting surface 8 and the mounting surface 9 are formed in a quadrilateral shape in a plan view as viewed from a normal direction Z thereto. The mounting surface 9 is a surface that opposes a connection object in a state that the semiconductor module 1 is mounted on the connection object. Examples of the connection object include a circuit board such as a PCB (Printed Circuit Board).

The side walls 10A to 10D include a first side wall 10A, a second side wall 10B, a third side wall 10C and a fourth side wall 10D. The first side wall 10A and the second side wall 10B extend along a first direction X and oppose each other in a second direction Y orthogonal to the first direction X. The third side wall 10C and the fourth side wall 10D extend in the second direction Y and oppose each other in the first direction X.

The plurality of die pads 3 are disposed inside the package main body 2. In this embodiment, the plurality of die pads 3 are each formed in a rectangular parallelepiped shape. The plurality of die pads 3 include a first die pad 3A and a second die pad 3B. The first die pad 3A is disposed at the fourth side wall 10D side. The second die pad 3B is disposed at the third side wall 10C side at an interval from the first die pad 3A.

The plurality of lead terminals 4 are respectively disposed at the third side wall 100 side and the fourth side wall 10D side of the package main body 2. Each lead terminal 4 has one end portion positioned inside the package main body 2 and the other end portion positioned outside the package main body 2. The other end portion of each lead terminal 4 is formed as an external connection portion that is connected to the connection object.

The semiconductor device 5 is disposed on the first die pad 3A inside the package main body 2. In this embodiment, the semiconductor device 5 is formed in a rectangular shape in a plan view. The semiconductor device 5 is disposed on the first die pad 3A in an orientation that its long sides oppose the third side wall 100 (fourth side wall 10D).

The semiconductor device 5 includes a plurality of low potential terminals 11 and a plurality of high potential terminals 12. The plurality of low potential terminals 11 are disposed at an interval along the long side of the semiconductor device 5 at the fourth side wall 10D side. The plurality of high potential terminals 12 are disposed at an interval along the long sides of the semiconductor device 5 in a substantially central portion at the third side wall 100 side and at the fourth side wall 10D side.

The controller IC 6 is disposed on the first die pad 3A inside the package main body 2. Specifically, the controller IC 6 is disposed on the first die pad 3A at an interval to the fourth side wall 10D side from the semiconductor device 5. In this embodiment, the controller IC 6 is formed in a rectangular shape in a plan view. The controller IC 6 is disposed on the first die pad 3A in an orientation that its long sides oppose the third side wall 100 (fourth side wall 10D).

The controller IC 6 includes a plurality of first input pads 13 and a plurality of first output pads 14. The plurality of first input pads 13 are disposed at an interval along the long side of the controller IC 6 at the fourth side wall 10D side. The plurality of first output pads 14 are disposed at an interval along the long side of the controller IC 6 at the third side wall 100 side.

The driver IC 7 is disposed on the second die pad 3B inside the package main body 2. In this embodiment, the driver IC 7 is formed in a rectangular shape in a plan view. The driver IC 7 is disposed on the second die pad 3B in an orientation that its long sides oppose the third side wall 100 (fourth side wall 10D).

The driver IC 7 includes a plurality of second input pads 15 and a plurality of second output pads 16. The plurality of second input pads 15 are disposed at an interval along the long side of the driver IC 7 at the fourth side wall 10D side. The plurality of second output pads 16 are disposed at an interval along the long side of the driver IC 7 at the third side wall 100 side.

The plurality of lead wires 17 to 20 selectively connect the plurality of lead terminals 4, the semiconductor device 5, the controller IC 6 and the driver IC 7 inside the package main body 2. The plurality of lead wires 17 to 20 are each constituted of a bonding wire. The plurality of lead wires 17 to 20 include at least one among a copper wire, a gold wire and an aluminum wire.

The plurality of lead wires 17 to 20 include first lead wires 17, second lead wires 18, third lead wires 19, and fourth lead wires 20. The first lead wires 17 are connected to the lead terminal 4 at the fourth side wall 10D side and the first input pad 13 of the controller IC 6. The second lead wires 18 are connected to the low potential terminal 11 of the semiconductor device 5 and the first output pad 14 of the controller IC 6. The third lead wires 19 are connected to the high potential terminal 12 of the semiconductor device 5 and the second input pad 15 of the driver IC 7. The fourth lead wires 20 are connected to the second output pad 16 of the driver IC 7 and the lead terminal 4 at the third side wall 100 side.

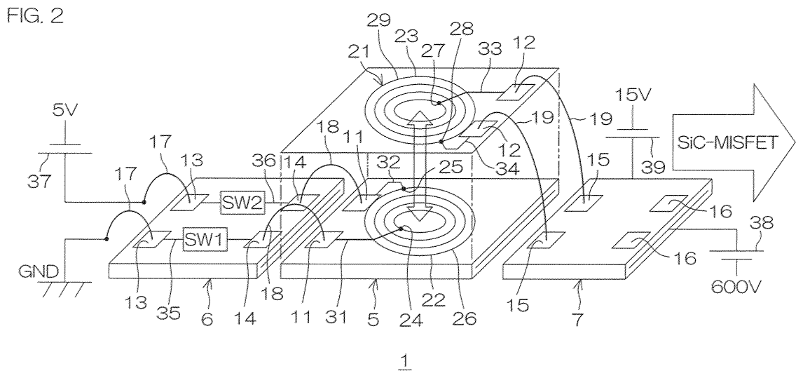

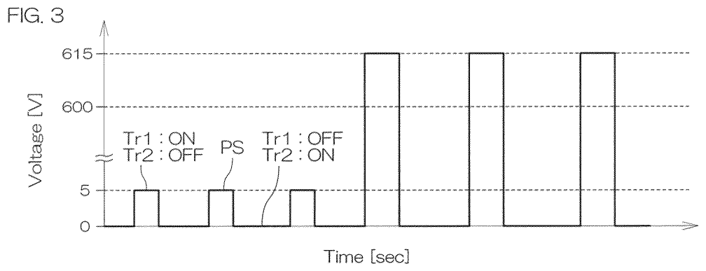

FIG. 2 is a diagram for describing an operation of the semiconductor module 1 shown in FIG. 1. FIG. 3 is a voltage waveform diagram used in the description of FIG. 2.

With reference to FIG. 2, the semiconductor device 5 includes a transformer 21. The transformer 21 includes a low potential coil 22 (low potential conductor pattern) as an example of the first conductive layer of the present disclosure at a primary side and a high potential coil 23 (high potential conductor pattern) as an example of the second conductive layer of the present disclosure at a secondary side that oppose each other in an up/down direction. The high potential coil 23 is disposed at an upper side with respect to the low potential coil 22 and opposes the low potential coil 22.

The high potential coil 23 is AC connected by magnetic coupling to the low potential coil 22 and at the same time is DC isolated from the low potential coil 22. That is, the driver IC 7 is AC connected to the controller IC 6 via the semiconductor device 5 and at the same time is DC isolated from the controller IC 6 by the semiconductor device 5.

The low potential coil 22 includes a first inner terminal end 24, a first outer terminal end 25, and a first spiral portion 26 that is routed in a spiral between the first inner terminal end 24 and the first outer terminal end 25. The high potential coil 23 includes a second inner terminal end 27, a second outer terminal end 28, and a second spiral portion 29 that is routed in a spiral between the second inner terminal end 27 and the second outer terminal end 28.

The semiconductor device 5 includes a first low potential wiring 31, a second low potential wiring 32, a first high potential wiring 33, and a second high potential wiring 34. The first low potential wiring 31 connects the first inner terminal end 24 of the low potential coil 22 to the corresponding low potential terminal 11. The second low potential wiring 32 connects the first outer terminal end 25 of the low potential coil 22 to the corresponding low potential terminal 11. The first high potential wiring 33 connects the second inner terminal end 27 of the high potential coil 23 to the corresponding high potential terminal 12. The second high potential wiring 34 connects the second outer terminal end 28 of the high potential coil 23 to the corresponding high potential terminal 12.

The controller IC 6 includes a first wiring 35 and a second wiring 36. The first wiring 35 is connected to the corresponding first input pad 13 and first output pad 14. The second wiring 36 is connected to the corresponding first input pad 13 and first output pad 14. The controller IC 6 further includes a first switching device Sw1 and a second switching device Sw2. The first switching device Sw1 and the second switching device Sw2 are each constituted of a transistor.

The first switching device Sw1 is interposed in the first wiring 35. The first switching device Sw1 controls conduction and interruption of an electrical signal transmitted to the first wiring 35. The second switching device Sw2 is interposed in the second wiring 36. The second switching device Sw2 controls conduction and interruption of an electrical signal transmitted to the second wiring 36.

The first input pad 13 at the first wiring 35 side is connected to a ground potential via a first lead wire 17. The first output pad 14 at the first wiring 35 side is electrically connected to the low potential terminal 11 at the first inner terminal end 24 side via a second lead wire 18. The first input pad 13 at the second wiring 36 side is electrically connected to a power supply 37 via a first lead wire 17. The power supply 37 applies a voltage, for example, of 5V to the controller IC 6. The first output pad 14 at the second wiring 36 side is electrically connected to the low potential terminal 11 at the first outer terminal end 25 side via a second lead wire 18.

The driver IC 7 is electrically connected to the semiconductor device 5 via the plurality of third lead wires 19. Specifically, a second input pad 15 of the driver IC 7 is electrically connected to the high potential terminal 12 at the second inner terminal end 27 side via a third lead wire 19. Also, the second input pad 15 of the driver IC 7 is electrically connected to the high potential terminal 12 at the second outer terminal end 28 side via the third lead wire 19.

A reference voltage power supply 38, a power supply 39 and an SiC-MISFET (Metal Insulator Semiconductor Field Effect Transistor) as an example of the load are connected to the driver IC 7.

Here, the semiconductor device 5 is an insulating element for transmitting a PWM control signal and other electrical signals in an insulation state. The driver IC 7 needs a voltage higher than that of the controller IC 6 to cause a significant difference in potential between the controller IC 6 and the driver IC 7, thereby necessitating the semiconductor device 5. Specifically, for example, in an inverter device of an electric vehicle or a hybrid electric vehicle, a power supply voltage supplied to the controller IC 6 is approximately 5 V or 3.3 V based on a ground potential.

In contrast thereto, as compared with a ground potential of the controller IC 6, a voltage of not less than 600 V, for example, is transitionally applied to the driver IC 7. More specifically, in a motor driver circuit used in the inverter device of the hybrid electric vehicle, etc., generally used is a half-bridge circuit in which a low side switching element is connected to a high side switching element in a totem pole configuration.

In an insulation gate driver, a switch that is turned on at any given time is only one of the low side switching element and the high side switching element. In a high-voltage system, a source of the low side switching element and a reference potential of the insulation gate driver which drives the switching element are connected to a ground potential and, therefore, a gate-source voltage is operated on the basis of the ground potential. On the other hand, a source of the high side switching element and a reference potential of the insulation gate driver which drives the switching element is connected to an output node of a half-bridge circuit. The output node of the half-bridge circuit is changed in potential depending on whether one of the low side switching element and the high side switching element is turned on, and the insulation gate driver which drives the high side switching element is accordingly changed in reference potential. When the high side switching element is turned on, the reference potential becomes a voltage equal to a voltage applied to a drain of the high side switching element (for example, not less than 600 V).

Where the semiconductor module 1 is used as the insulation gate driver which drives the high side switching element, a ground potential of the driver IC 7 is separated from that of the controller IC 6 to secure insulation properties. Therefore, as compared with the ground potential of the controller IC 6, a voltage of 600 V or more is transitionally applied to the driver IC 7. Thus, in particular, in the insulation gate driver which drives the high side switching element, as compared with the ground potential of the controller IC 6, a voltage of 600 V or more is transitionally applied to the driver IC 7.

With reference to FIG. 3, the controller IC 6 performs on/off control of the first switching device Sw1 and the second switching device Sw2 in a predetermined switching pattern to generate a pulse signal PS. In this example, the predetermined switching pattern includes a first application state (Sw1: On, Sw2: Off) and a second application state (Sw1: Off, Sw2: On). FIG. 3 shows an example where the pulse signal PS of 5 V, with 0 V (ground potential) as a reference, is generated.

The pulse signal PS generated by the controller IC 6 is input into the semiconductor device 5. The semiconductor device 5 transmits the pulse signal PS from the low potential coil 22 to the high potential coil 23. The pulse signal PS is thereby boosted by an amount that is in accordance with a winding ratio (transformation ratio) of the low potential coil 22 in relation to the high potential coil 23.

The boosted pulse signal PS is input into the driver IC 7. The driver IC 7 generates an electrical signal that is in accordance with the boosted pulse signal PS to drive and control the SiC-MISFET. For example, FIG. 3 shows a gate potential waveform in which the semiconductor module 1 is used as the insulation gate driver for driving the above-described high side switching element. In FIG. 3, a waveform of a pulse width of 0 V to 5 V indicates a gate output waveform of the controller IC 6, and a waveform of a pulse width of 0 V to 615 V indicates a gate output waveform of the insulation gate driver (driver IC 7) which drives the high side switching element.

A pulse signal of 15 V, with the source of the high side switching element given as a reference, is applied to the high side switching element. Therefore, a signal of 0 V to 615 V, with the ground potential at the secondary side given as a reference, is to be applied to the high side switching element. It is noted that the numerical values indicated in FIG. 2 and FIG. 3 are all merely examples. For example, the reference voltage at the secondary side (high potential side) may be not less than 500 V and not more than 4000 V.

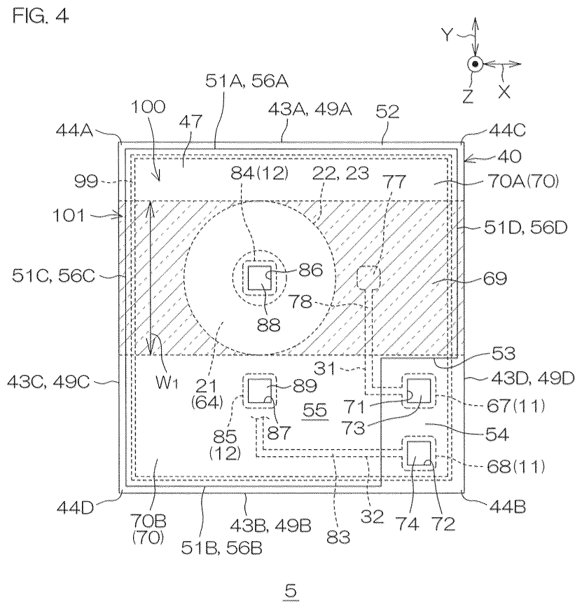

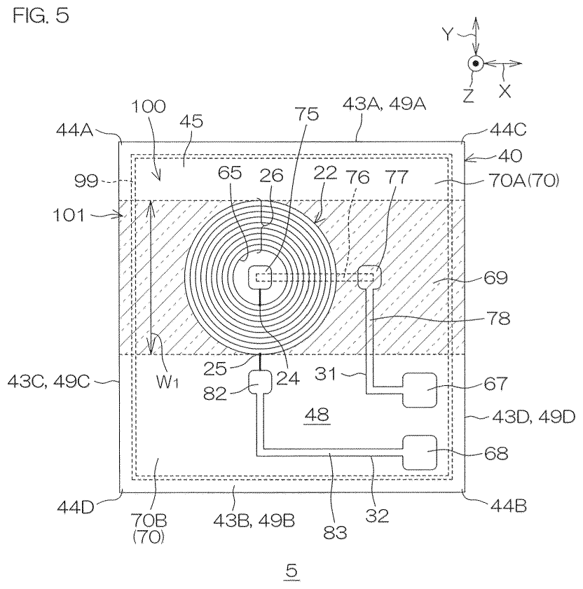

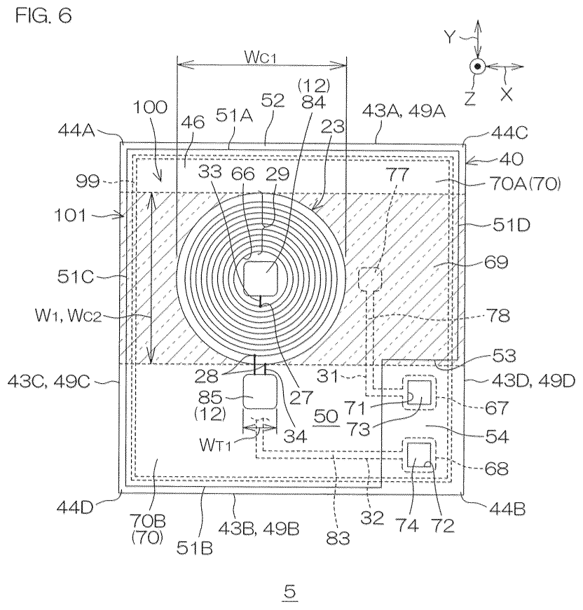

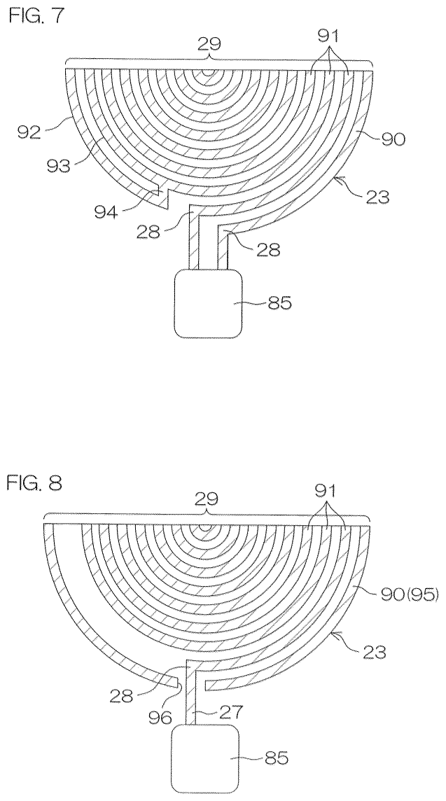

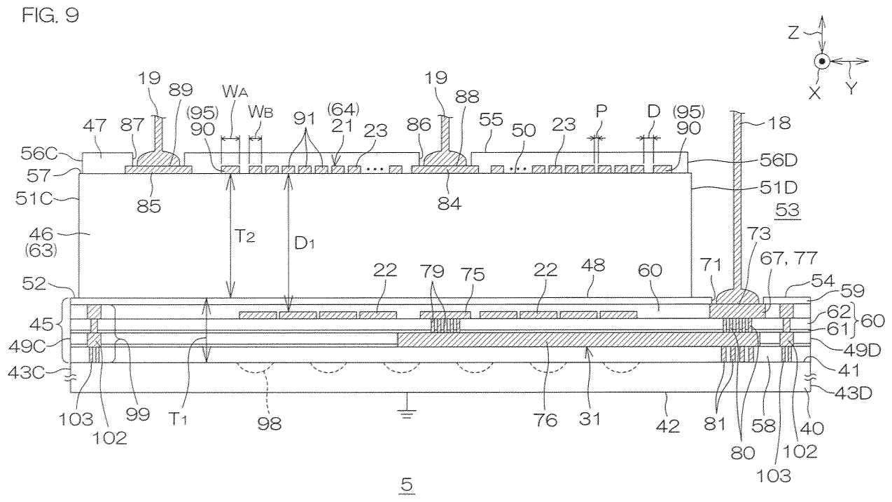

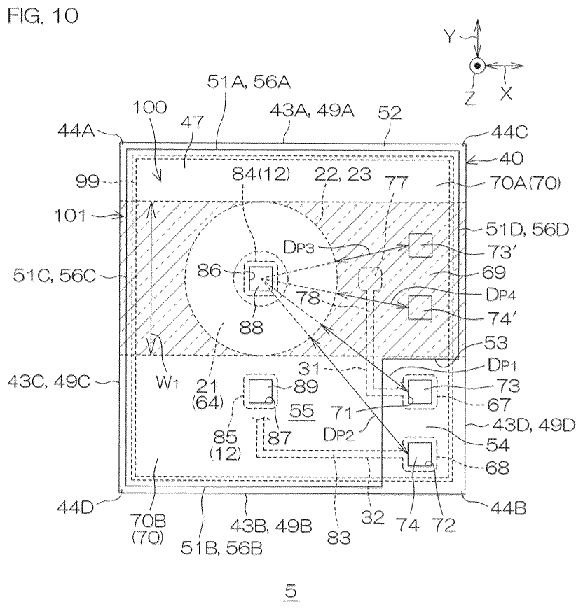

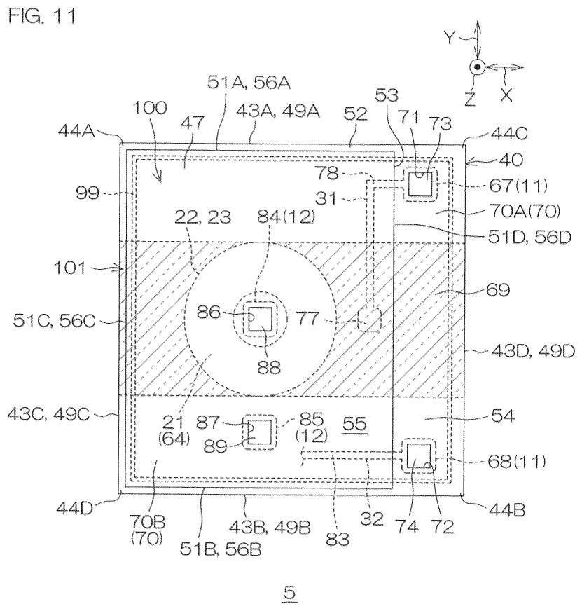

FIG. 4 is a schematic plan view of a semiconductor device 5 according to a preferred embodiment of the present disclosure. FIG. 5 is a plan view that shows a layer in which the low potential coil 22 is formed in the semiconductor device 5 shown in FIG. 4. FIG. 6 is a plan view that shows a layer in which the high potential coil 23 is formed in the semiconductor device 5 shown in FIG. 4. FIG. 7 is an enlarged view of main parts of the high potential coil 23 shown in FIG. 6. FIG. 8 is an enlarged view of main parts of the high potential coil 23 in FIG. 6. FIG. 9 is a schematic sectional view of the semiconductor device 5 shown in FIG. 4. FIG. 10 is a diagram for describing the effects of the semiconductor device 5 shown in FIG. 4. It is noted that FIG. 9 is a sectional view of the semiconductor device 5 but does not show a cross section obtained when the semiconductor device 5 is cut in a specific direction.

With reference to FIG. 4 to FIG. 6 and FIG. 9, the semiconductor device 5 includes a semiconductor chip 40 of rectangular parallelepiped shape. The semiconductor chip 40 contains at least one among silicon, a wide bandgap semiconductor, and a compound semiconductor.

The wide bandgap semiconductor is constituted of a semiconductor that exceeds the bandgap (approximately 1.12 eV) of silicon. The bandgap of the wide bandgap semiconductor is preferably not less than 2.0 eV. The wide bandgap semiconductor may be Sic (silicon carbide). The compound semiconductor may be a group III-V compound semiconductor. The compound semiconductor may include at least one among AlN (aluminum nitride), InN (indium nitride), GaN (gallium nitride), and GaAs (gallium arsenide).

In this embodiment, the semiconductor chip 40 includes a semiconductor substrate made of silicon. The semiconductor chip 40 may be an epitaxial substrate having a laminated structure that includes a semiconductor substrate made of silicon and an epitaxial layer made of silicon. A conductive type of the semiconductor substrate may be an n type or a p type. The epitaxial layer may be of an n type or a p type.

The semiconductor chip 40 has a first principal surface 41 at one side, a second principal surface 42 at the other side, and chip side walls 43A to 43D connecting the first principal surface 41 and the second principal surface 42. The first principal surface 41 and the second principal surface 42 are formed in a quadrilateral shape (square shape in this embodiment) in a plan view as viewed from the normal direction Z thereto (hereinafter, simply referred to as “plan view”).

The chip side walls 43A to 43D include a first chip side wall 43A as an example of the first side of the present disclosure, a second chip side wall 43B as an example of the second side of the present disclosure, a third chip side wall 43C as an example of the third side of the present disclosure, and a fourth chip side wall 43D as an example of the fourth side of the present disclosure. The first chip side wall 43A and the second chip side wall 43B extend along the first direction X and oppose each other in the second direction Y. The third chip side wall 43C and the fourth chip side wall 43D extend in the second direction Y and oppose each other in the first direction X. The chip side walls 43A to 43D may be constituted of a ground surface.

The semiconductor chip 40 in a quadrilateral shape in a plan view has a first corner portion 44A and a second corner portion 44B which are diagonal to each other as well as a third corner portion 44C and a fourth corner portion 44D which are diagonal to each other. The first corner portion 44A and the third corner portion 44C are formed at both end portions of the first chip side wall 43A. The second corner portion 44B and the fourth corner portion 44D are formed at both end portions of the second chip side wall 43B.

The semiconductor device 5 includes a first insulating portion 45, a second insulating portion 46, and a protective layer 47 that are sequentially formed on the first principal surface 41 of the semiconductor chip 40.

The first insulating portion 45 has an insulating principal surface 48 and insulating side walls 49A to 49D. The insulating principal surface 48 is formed in a quadrilateral shape (in a rectangular shape in this embodiment) in alignment with the first principal surface 41 in a plan view. The insulating principal surface 48 extends in parallel to the first principal surface 41. The insulating side walls 49A to 49D include a first insulating side wall 49A, a second insulating side wall 49B, a third insulating side wall 49C, and a fourth insulating side wall 49D. The insulating side walls 49A to 49D extend from a peripheral edge of the insulating principal surface 48 toward the semiconductor chip 40 and continue to the chip side walls 43A to 43D. Specifically, the insulating side walls 49A to 49D are formed so as to be flush with the chip side walls 43A to 43D. The insulating side walls 49A to 49D form ground surfaces that are flush with the chip side walls 43A to 43D.

The second insulating portion 46 is formed on the insulating principal surface 48 and has an insulating principal surface 50 and insulating side walls 51A to 51D. The insulating principal surface 50 extends in parallel to the first principal surface 41. The insulating side walls 51A to 51D include a first insulating side wall 51A, a second insulating side wall 51B, a third insulating side wall 51C, and a fourth insulating side wall 51D. The insulating side walls 51A to 51D extend from a peripheral edge of the insulating principal surface 50 toward the semiconductor chip 40. Specifically, the insulating side walls 51A to 51D are formed internally with respect to the insulating side walls 49A to 49D. Thereby, a step 52 is formed between the insulating side walls 49A to 49D and the insulating side walls 51A to 51D.

Further, in this embodiment, a recessed portion 53 that is depressed internally in a plan view is formed in the second insulating portion 46. The recessed portion 53 is formed by removing a part of the second insulating portion 46 from the insulating principal surface 50 to the insulating principal surface 48 of the first insulating portion 45. Thereby, a part of the first insulating portion 45 is exposed in the recessed portion 53 of the second insulating portion 46. In this embodiment, a step is formed on the third insulating side wall 51C so that the second insulating portion 46 will be selectively depressed at the second corner portion 44B of the semiconductor chip 40 in a plan view, by which the recessed portion 53 is formed. Thereby, the second insulating portion 46 may be formed in an L-letter shape in a plan view. The part of the first insulating portion 45 that is exposed from the recessed portion 53 forms a pad region 54 in which a plurality of low potential terminals 67, 68 are disposed.

The protective layer 47 is formed on the insulating principal surface 50 of the second insulating portion 46 and has a protective principal surface 55 and protective side walls 56A to 56D. The protective principal surface 55 is formed in an L-letter shape in a plan view that is similar to the insulating principal surface 50 of the second insulating portion 46 in a plan view. The protective principal surface 55 extends in parallel to the first principal surface 41. The protective side walls 56A to 56D include a first protective side wall 56A, a second protective side wall 56B, a third protective side wall 56C, and a fourth protective side wall 56D. The protective side walls 56A to 56D extend from a peripheral edge of the protective principal surface 55 toward the semiconductor chip 40. Specifically, the protective side walls 56A to 56D are formed internally with respect to the insulating side walls 51A to 51D. Thereby, a step 57 is formed between the protective side walls 56A to 56D and the insulating side walls 51A to 51D.

With reference to FIG. 9, the first insulating portion 45 is constituted of a multilayer insulating laminated structure that includes a lowermost insulating layer 58, an uppermost insulating layer 59, and a plurality (three in this embodiment) of interlayer insulating layers 60. The lowermost insulating layer 58 is an insulating layer that directly covers the first principal surface 41 of the semiconductor chip 40. The uppermost insulating layer 59 is an insulating layer that forms the insulating principal surface 48 of the first insulating portion 45. The plurality of interlayer insulating layers 60 are insulating layers that are interposed between the lowermost insulating layer 58 and the uppermost insulating layer 59. In this embodiment, the lowermost insulating layer 58 has a single layer structure that contains silicon oxide. In this embodiment, the uppermost insulating layer 59 has a single layer structure that contains silicon nitride. A thickness of the lowermost insulating layer 58 and a thickness of the uppermost insulating layer 59 may each be not less than 0.5 μm and not more than 5 μm (for example, approximately 2 μm).

The plurality of interlayer insulating layers 60 may have a laminated structure that includes a first insulating layer 61 at the lowermost insulating layer 58 side and a second insulating layer 62 at the uppermost insulating layer 59 side. In this case, the first insulating layer 61 is constituted of an inorganic insulating layer and may contain, for example, silicon nitride. The first insulating layer 61 is formed as an etching stopper layer with respect to the second insulating layer 62. A thickness of the first insulating layer 61 may be not less than 0.1 μm and not more than 2 μm (for example, approximately 0.3 μm).

The second insulating layer 62 is formed on the first insulating layer 61. It contains an insulating material different from the first insulating layer 61. The second insulating layer 62 is constituted of an inorganic insulating layer different from the first insulating layer 61 and may contain, for example, silicon oxide. A thickness of the second insulating layer 62 may be not less than 0.5 μm and not more than 5 μm (for example, approximately 2 μm). The thickness of the second insulating layer 62 preferably exceeds the thickness of the first insulating layer 61.

Further, the first insulating layer 61 may be a compressive stress film and the second insulating layer 62 may be a tensile stress film. That is, the interlayer insulating layer 60 may be structured so that the compressive stress film and the tensile stress film are repeatedly laminated. It is, thereby, possible to form the first insulating layer 61, while cancelling a stress in a lamination interface of the interlayer insulating layer 60. As a result, a semiconductor wafer which serves as a base of the semiconductor chip 40 can be prevented from occurrence of a large warpage deformation in a process of manufacturing the semiconductor device 5. The compressive stress film may be, for example, a silicon oxide film, and the tensile stress film may be, for example, a silicon nitride film.

Further, the interlayer insulating layer 60 may include a layer that is constituted of a single layer structure of, for example, the second insulating layer 62. In this embodiment, the interlayer insulating layer 60 in contact with the uppermost insulating layer 59 is a layer that is constituted of a single layer of the second insulating layer 62.

A total thickness T1 of the first insulating portion 45 may be not less than 2 μm and not more than 30 μm. The total thickness T1 of the first insulating portion 45 and the number of laminated layers of the interlayer insulating layers 60 are arbitrary and adjusted in accordance with a dielectric withstand voltage (dielectric breakdown resistance) to be realized. Also, insulating materials of the lowermost insulating layer 58, the uppermost insulating layer 59 and the interlayer insulating layer 60 are arbitrary and not restricted to specific insulating materials.

The second insulating portion 46 is constituted of an insulating material having a dielectric constant different from the first insulating layer 61 and the second insulating layer 62 and has a layered structure that includes, for example, an organic insulating layer 63. In this embodiment, the second insulating portion 46 is constituted of a single layer of the organic insulating layer 63 but may be a laminated structure made of the plurality of organic insulating layers 63. As the organic insulating layer 63, for example, a polyimide film, a phenol resin film, an epoxy resin film, etc., are included. A total thickness T₂ of the second insulating portion 46 may be not less than 5 μm and not more than 100 μm. The total thickness T₂ of the second insulating portion 46 is arbitrary and adjusted in accordance with a dielectric withstand voltage (dielectric breakdown resistance) to be realized.

The protective layer 47 protects the second insulating portion 46, the first insulating portion 45, and the semiconductor chip 40 from above the insulating principal surface 50. The protective layer 47 may be constituted of an organic insulating layer and may contain a photosensitive resin. The protective layer 47 may contain at least one among polyimide, polyamide and polybenzoxazole. In this embodiment, the protective layer 47 contains polyimide.

The semiconductor device 5 includes a first functional device 64 that is formed on the semiconductor chip 40. The first functional device 64 includes one or a plurality (one in this embodiment) of transformers 21. The transformer 21 is formed at an inner portion of a laminated structure of the first insulating portion 45 and the second insulating portion 46. With reference to FIG. 4, in this embodiment, the transformer 21 is disposed so as to be close to the first corner portion 44A of the semiconductor chip 40 in a plan view. Here, that the transformer 21 is disposed so as to be close to the first corner portion 44A may mean that the transformer 21 is disposed at a side close to the first corner portion 44A with respect to, for example, a constitution having a relationship of making a pair with the first corner portion 44A (the second corner portion 44B in this embodiment).

With reference to FIG. 5, FIG. 6 and FIG. 9, the transformer 21 includes the low potential coil 22 and the high potential coil 23. The low potential coil 22 is formed inside the first insulating portion 45. The high potential coil 23 is formed on the second insulating portion 46 so as to oppose the low potential coil 22 in the normal direction Z.

With reference to FIG. 9, in this embodiment, the low potential coil 22 is formed in a region held between the lowermost insulating layer 58 and the uppermost insulating layer 59 (that is, the plurality of interlayer insulating layers 60). With reference to FIG. 9, the high potential coil 23 is formed in the insulating principal surface 50 of the second insulating portion 46. That is, the high potential coil 23 opposes the semiconductor chip 40 across the low potential coil 22. The low potential coil 22 and the high potential coil 23 may be disposed at any arbitrary site in the normal direction Z. Also, the high potential coil 23 may oppose the low potential coil 22 across the second insulating portion 46.

A distance D1 between the low potential coil 22 and the high potential coil 23 (that is, a thickness of the uppermost insulating layer 59 and that of the second insulating portion 46) is adjusted as appropriate in accordance with a dielectric withstand voltage and a field intensity between the low potential coil 22 and the high potential coil 23. In this embodiment, the low potential coil 22 is formed in the uppermost interlayer insulating layer 60 as counted from the lowermost insulating layer 58 side. More specifically, the low potential coil 22 is formed on the interlayer insulating layer 60 that is a laminated structure of the first insulating layer 61 and the second insulating layer 62 and also may be covered by the interlayer insulating layer 60 that is constituted of a single layer of the second insulating layer 62 and also by the uppermost insulating layer 59. On the other hand, the high potential coil 23 is formed in the insulating principal surface 50 of the second insulating portion 46. Therefore, the uppermost insulating layer 59 and the second insulating portion 46 are interposed between the low potential coil 22 and the high potential coil 23.

With reference to FIG. 5, the low potential coil 22 includes a first inner terminal end 24, a first outer terminal end 25, and a first spiral portion 26 that is routed in a spiral between the first inner terminal end 24 and the first outer terminal end 25. The first spiral portion 26 is routed in a spiral that extends in a circular shape in a plan view. A portion of the first spiral portion 26 that forms an innermost peripheral edge demarcates a first inner region 65 that is a circular shape in a plan view.

The number of windings of the first spiral portion 26 may be not less than 5 and not more than 30. A width of the first spiral portion 26 may be not less than 0.1 μm and not more than 5 μm. The width of the first spiral portion 26 is preferably not less than 1 μm and not more than 3 μm. The width of the first spiral portion 26 is defined by a width in a direction orthogonal to a spiral direction. A first winding pitch of the first spiral portion 26 may be not less than 0.1 μm and not more than 5 μm. The first winding pitch is preferably not less than 1 μm and not more than 3 μm. The first winding pitch is defined by a distance between two portions of the first spiral portion 26 that are adjacent to each other in the direction orthogonal to the spiral direction.

A winding shape of the first spiral portion 26 and a planar shape of the first inner region 65 are arbitrary and are not restricted to the mode shown in FIG. 5, etc. The first spiral portion 26 may be wound in a polygonal shape such as a triangular shape, a quadrilateral shape, etc., or in an elliptical shape in a plan view. The first inner region 65 may be demarcated in a polygonal shape such as a triangular shape, a quadrilateral shape, etc., or in an elliptical shape in a plan view in accordance with the winding shape of the first spiral portion 26.

The low potential coil 22 may contain at least one among titanium (Ti), titanium nitride (TiN), copper (Cu), aluminum (Al) and tungsten (W). In this embodiment, the low potential coil 22 is constituted of an aluminum-copper based alloy (AlCu). The aluminum-copper based alloy is an alloy material that mainly contains Al and Cu and may also contain a small quantity of alloy components other than Al and Cu. It may contain, for example, Si, Mg, etc. In this case, the aluminum-copper based alloy may be expressed as Al—Si—Cu, Al—Si—Mg, Al—Si—Cu—Mg, etc.

With reference to FIG. 9, the high potential coil 23 is formed so as to be set up on the opposite side of the first insulating portion 45 from the insulating principal surface 50 of the second insulating portion 46. The high potential coil 23 is covered by the protective layer 47 from the top side thereof. The high potential coil 23 may also have a thickness larger than that of the low potential coil 22.

With reference to FIG. 6, the high potential coil 23 includes a second inner terminal end 27, a second outer terminal end 28, and a second spiral portion 29 that is routed in a spiral between the second inner terminal end 27 and the second outer terminal end 28. The second spiral portion 29 is routed in a spiral that extends in a circular shape in a plan view. A portion of the second spiral portion 29 that forms an innermost peripheral edge demarcates a second inner region 66 that is a circular shape in a plan view. The second inner region 66 of the second spiral portion 29 opposes the first inner region 65 of the first spiral portion 26 in the normal direction Z.

The number of windings of the second spiral portion 29 may be not less than 5 and not more than 30. The number of windings of the second spiral portion 29 with respect to the number of windings of the first spiral portion 26 is adjusted in accordance with a voltage value to be boosted. The number of windings of the second spiral portion 29 preferably exceeds the number of windings of the first spiral portion 26. As a matter of course, the number of windings of the second spiral portion 29 may be less than the number of windings of the first spiral portion 26 or may be equal to the number of windings of the first spiral portion 26.

A width of the second spiral portion 29 may be not less than 0.1 μm and not more than 5 μm. The width of the second spiral portion 29 is preferably not less than 1 μm and not more than 3 μm. The width of the second spiral portion 29 is defined by a width in the direction orthogonal to the spiral direction. The width of the second spiral portion 29 is preferably equal to the width of the first spiral portion 26.

A second winding pitch of the second spiral portion 29 may be not less than 0.1 μm and not more than 5 μm. The second winding pitch is preferably not less than 1 μm and not more than 3 μm. The second winding pitch is defined by a distance between two portions of the second spiral portion 29 that are adjacent to each other in the direction orthogonal to the spiral direction. The second winding pitch is preferably equal to the first winding pitch of the first spiral portion 26.

A winding shape of the second spiral portion 29 and a planar shape of the second inner region 66 are arbitrary and are not restricted to the mode shown in FIG. 6, etc. The second spiral portion 29 may be wound in a polygonal shape such as a triangular shape, a quadrilateral shape, etc., or in an elliptical shape in a plan view. The second inner region 66 may be demarcated in a polygonal shape such as a triangular shape, a quadrilateral shape, etc., or in an elliptical shape in a plan view in accordance with the winding shape of the second spiral portion 29. Further, a part of the protective layer 47 enters into a gap of the second spiral portion 29.

The high potential coil 23 may contain at least one among titanium (Ti), titanium nitride (TiN), copper (Cu), aluminum (Al) and tungsten (W). In this embodiment, the high potential coil 23 is constituted of Cu. The high potential coil 23 which is constituted of Cu may be formed by growing, for example, Cu by plating.

With reference to FIG. 4 to FIG. 6 and FIG. 9, as a structure that is related to the low potential coil 22, the semiconductor device 5 includes a first low potential terminal 67, a second low potential terminal 68, a first low potential wiring 31 and a second low potential wiring 32. The first low potential terminal 67 and the second low potential terminal 68 are the previously described low potential terminal 11. It is noted that in FIG. 4 and FIG. 6, the second low potential wiring 32 is partially omitted for clarification.

The first low potential terminal 67 and the second low potential terminal 68 are each formed in an island shape and formed in a second region 70 apart from a first region 69 that opposes the high potential coil 23 in the first direction X in a plan view. As shown in FIG. 4 to FIG. 6, the first region 69 is a region that overlaps the high potential coil 23 (a region to which hatching is given in FIG. 4 to FIG. 6) when the high potential coil 23 is projected in the first direction X, and the second region 70 is a region that does not overlap the high potential coil 23 (a region to which no hatching is given in FIG. 4 to FIG. 6). Therefore, a width W₁ of the first region 69 may be equal to a width W_{c2} of the high potential coil 23 in the second direction Y. More specifically, the first low potential terminal 67 and the second low potential terminal 68 are formed in the pad region 54 (second corner portion 44B of the semiconductor chip 40) that is exposed from the second insulating portion 46. In the pad region 54, the first low potential terminal 67 and the second low potential terminal 68 are arrayed at an interval in the second direction Y.

In this embodiment, the high potential coil 23 (transformer 21) is formed at an interval from each of the first chip side wall 43A and the second chip side wall 43B of the semiconductor chip 40 in a plan view. Therefore, the pair of second regions 70 that hold the first region 69 between them are formed in the second direction Y. The pair of second regions 70 may include a second region 70A at the first chip side wall 43A side and a second region 70B at the second chip side wall 43B side. In this embodiment, the pad region 54 is formed so as to selectively expose the second region 70B.

With reference to FIG. 9, the first low potential terminal 67 and the second low potential terminal 68 are each formed inside the interlayer insulating layer 60 in which the low potential coil 22 is formed. The first low potential terminal 67 and the second low potential terminal 68 are covered by the uppermost insulating layer 59. It is noted that in FIG. 9, only the first low potential terminal 67 is shown and the second low potential terminal 68 is omitted. A part of the first low potential terminal 67 and that of the second low potential terminal 68 are respectively exposed from a first pad opening 71 and a second pad opening 72 that are formed in the uppermost insulating layer 59 as a first low potential pad 73 and a second low potential pad 74. At least one of the first low potential pad 73 and the second low potential pad 74 may be an example of the first pad of the present disclosure. A second lead wire 18 (bonding wire) is connected to each of the first low potential pad 73 and the second low potential pad 74.

The first low potential wiring 31 electrically connects the first low potential terminal 67 and the low potential coil 22. The first low potential wiring 31 may include a first low potential connection portion 75, a first wiring 76 as an example of the first conductive member of the present disclosure, a second low potential connection portion 77, a second wiring 78, a first connection plug electrode 79, a second connection plug electrode 80, and a substrate plug electrode 81.

The first low potential connection portion 75, the first wiring 76, the second low potential connection portion 77, the second wiring 78, the first connection plug electrode 79, the second connection plug electrode 80, and the substrate plug electrode 81 may contain at least one among titanium (Ti), titanium nitride (TiN), copper (Cu), aluminum (Al) and tungsten (W). The first low potential connection portion 75, etc., may have a laminated structure that includes a barrier layer and a main body layer. The barrier layer demarcates a recess space inside the interlayer insulating layer 60. The main body layer is embedded in the recess space demarcated by the barrier layer. The barrier layer may contain at least one of titanium and titanium nitride. The main body layer may contain at least one among copper, aluminum and tungsten.

The first low potential connection portion 75 is formed in the first inner region 65 of the transformer 21 (low potential coil 22) inside the interlayer insulating layer 60 in which the low potential coil 22 is formed. The first low potential connection portion 75 is formed in an island shape and opposes the high potential terminal (first high potential terminal 84) in the normal direction Z. The first low potential connection portion 75 is electrically connected to the first inner terminal end 24 of the low potential coil 22.

The first wiring 76 is formed inside the interlayer insulating layer 60. In this embodiment, the first wiring 76 is formed inside the first interlayer insulating layer 60 as counted from the lowermost insulating layer 58 and extends by crossing the low potential coil 22 below the low potential coil 22. The first wiring 76 includes a first end portion at one side, a second end portion at the other side and a wiring portion that connects the first end portion and the second end portion. The first end portion of the first wiring 76 is positioned in a region between the semiconductor chip 40 and the first low potential connection portion 75. The second end portion of the first wiring 76 is positioned in a region between the semiconductor chip 40 and the second low potential connection portion 77. The wiring portion extends along the first direction X and extends as a band (linearly) in a region between the first end portion and the second end portion.

The second low potential connection portion 77 is a portion which relays the first wiring 76 and the second wiring 78. The second low potential connection portion 77 is formed inside the interlayer insulating layer 60 in which the low potential coil 22 is formed. The second low potential connection portion 77 is formed in an island shape and opposes the first low potential connection portion 75 across a part of the first spiral portion 26 of the low potential coil 22 in the first direction X. As shown in FIG. 5, a space between the first low potential connection portion 75 and the second low potential connection portion 77 is connected at a relatively short distance by the linear first wiring 76 that extends by crossing below the low potential coil 22. It is thereby possible to decrease a wiring resistance of the first low potential wiring 31.

The second wiring 78 extends between the second low potential connection portion 77 and the first low potential terminal 67 inside the interlayer insulating layer 60 in which the low potential coil 22 is formed, thereby connecting the second low potential connection portion 77 and the first low potential terminal 67. It is noted that in FIG. 9, for the sake of convenience of description, the second low potential connection portion 77 and the first low potential terminal 67 are shown as the same constituent. Also, as shown in FIG. 4 and FIG. 6, the second wiring 78 is formed across inside and outside the pad region 54. Therefore, a part of the second wiring 78 is formed in the pad region 54 and a remaining part of the second wiring 78 is formed outside the pad region 54 and covered by the second insulating portion 46.

The first connection plug electrode 79 is formed in a region between the first low potential connection portion 75 and the first wiring 76 inside the interlayer insulating layer 60 and electrically connected to the first low potential connection portion 75 and the first end portion of the first wiring 76. The second connection plug electrode 80 is formed in a region between the second low potential connection portion 77 and the first wiring 76 inside the interlayer insulating layer 60 and electrically connected to the second low potential connection portion 77 and the second end portion of the first wiring 76.

In this embodiment, the substrate plug electrode 81 is formed in a region between the semiconductor chip 40 and the second end portion of the first wiring 76 and electrically connected to each of the semiconductor chip 40 and the second end portion of the first wiring 76. The first low potential wiring 31 may be fixed at a ground potential by the substrate plug electrode 81.

The second low potential wiring 32 electrically connects the second low potential terminal 68 and the low potential coil 22. The second low potential wiring 32 may include a third low potential connection portion 82 and a third wiring 83. The third low potential connection portion 82 and the third wiring 83 are preferably formed of the same conductive material as the first low potential connection portion 75, etc. That is, the third low potential connection portion 82 and the third wiring 83 preferably include a barrier layer and a main body layer as with the first low potential connection portion 75, etc.

The third low potential connection portion 82 is formed inside the interlayer insulating layer 60 in which the low potential coil 22 is formed. The third low potential connection portion 82 is formed in an island shape and opposes the first low potential connection portion 75 across a part of the first spiral portion 26 of the low potential coil 22 in the second direction Y. The third low potential connection portion 82 is electrically connected to the first outer terminal end 25 of the low potential coil 22.

The third wiring 83 extends between the third low potential connection portion 82 and the second low potential terminal 68 inside the interlayer insulating layer 60 in which the low potential coil 22 is formed and connects the third low potential connection portion 82 and the second low potential terminal 68. Also, as shown in FIG. 4 and FIG. 6, the third wiring 83 is formed across inside and outside the pad region 54. Therefore, a part of the third wiring 83 is formed in the pad region 54 and a remaining part of the third wiring 83 is formed outside the pad region 54 and covered by the second insulating portion 46.

With reference to FIG. 4, FIG. 6 and FIG. 9, as a structure that is related to the high potential coil 23, the semiconductor device 5 includes a first high potential terminal 84, a second high potential terminal 85, a first high potential wiring 33 and a second high potential wiring 34. The first high potential terminal 84 and the second high potential terminal 85 are the high potential terminal 12 that has been described previously. The first high potential terminal 84, the second high potential terminal 85, the first high potential wiring 33 and the second high potential wiring 34 are preferably formed of the same conductive material as the high potential coil 23 in the insulating principal surface 50 of the second insulating portion 46. That is, the first high potential terminal 84, the second high potential terminal 85, the first high potential wiring 33 and the second high potential wiring 34 may be constituted of Cu that is formed by growing Cu by plating.

The first high potential terminal 84 is formed in an island shape and formed in the second inner region 66 of the transformer 21 (high potential coil 23) in a plan view. The second high potential terminal 85 is formed in an island shape and formed outside the second inner region 66 in a plan view. In this embodiment, the second high potential terminal 85 opposes the first high potential terminal 84 across a part of the second spiral portion 29 of the high potential coil 23 in the second direction Y. Therefore, the second high potential terminal 85 is formed in the second region 70. The second high potential terminal 85 may oppose the plurality of low potential terminals 67, 68 in the first direction X. Further, the second high potential terminal 85 has a width W_{T1} that is smaller than a width W_{C1} of the high potential coil 23 in the first direction X.

The first high potential terminal 84 and the second high potential terminal 85 are covered by the protective layer 47. A part of the first high potential terminal 84 and that of the second high potential terminal 85 are respectively exposed from a first pad opening 86 and a second pad opening 87 formed in the protective layer 47 as a first high potential pad 88 and a second high potential pad 89. The second high potential pad 89 may be an example of the second pad of the present disclosure. The third lead wire 19 (bonding wire) is connected to each of the first high potential pad 88 and the second high potential pad 89.

The first high potential wiring 33 connects the first high potential terminal 84 and the second inner terminal end 27 of the high potential coil 23. The second high potential wiring 34 connects the second high potential terminal 85 and the second outer terminal end 28 of the high potential coil 23. Here, with reference to FIG. 7 to FIG. 9, a structure of the high potential coil 23 will be described in more detail.

The second spiral portion 29 of the high potential coil 23 may include a first portion 90 that forms an outermost periphery of the second spiral portion 29 and a second portion 91 that forms the second spiral portion 29 which is further inside than the first portion 90. As shown in FIG. 9, the first portion 90 may have a first width W_{A} and the second portion 91 may have a second width W_{B} smaller than the first width W_{A}. Further, a distance D between the first portion 90 and a portion of an outermost periphery of the second portion 91 (that is, a second winding-number portion from the outermost periphery of the high potential coil 23) may be larger than a pitch P of the second portion 91. Still further, the second portion 91 of the high potential coil 23 may have a thickness larger than the pitch P of the second portion 91.

With reference to FIG. 7, the second high potential terminal 85 may be connected to both of the first portion 90 and the second portion 91 of the high potential coil 23. In this case, in a high potential coil 23, a double spiral structure which is constituted of a first spiral structure 92 continuing to the first portion 90 and a second spiral structure 93 continuing to the second portion 91 extends from the second high potential terminal 85 as a starting point. However, the first spiral structure 92 and the second spiral structure 93 may be made common by a connection portion 94 extending in a direction that crosses the spiral structure.

On the other hand, with reference to FIG. 8, the second high potential terminal 85 may be selectively connected to the second portion 91 of the high potential coil 23. In this case, the first portion 90 of the high potential coil 23 is electrically separated from the second portion 91. Therefore, only the second portion 91 of the high potential coil 23 may be referred to as the high potential coil 23 that contributes to functions of the transformer 21, while the first portion 90 of the high potential coil 23 may be referred to as a dummy pattern 95 that does not contribute to functions of the transformer 21. For example, the dummy pattern 95 is formed substantially in an annular shape, a part of which has an open portion 96, and the second high potential terminal 85 may be connected to the high potential coil 23 (second portion 91) by a connection portion 97 that passes through the open portion 96. The dummy pattern 95 may be, for example, connected at a ground potential or may be in an electrically floating state (not shown).

With reference to FIG. 9, the semiconductor device 5 includes a second functional device 98 formed in the first principal surface 41 of the semiconductor chip 40 in a device region 100 (to be described later). The second functional device 98 is formed by using a front layer portion of the first principal surface 41 of the semiconductor chip 40 and/or a region on the first principal surface 41 of the semiconductor chip 40 and covered by the first insulating portion 45 (lowermost insulating layer 58). In FIG. 9, the second functional device 98 is shown in a simplified manner by a dashed line indicated at the front layer portion of the first principal surface 41. The second functional device 98 is electrically connected to the low potential terminals 67, 68 via a low potential wiring and electrically connected to the high potential terminal via a high potential wiring.

The second functional device 98 may include at least one among a passive device, a semiconductor rectifying device and a semiconductor switching device. The second functional device 98 may include a circuit network in which any two or more types of devices among the passive device, the semiconductor rectifying device and the semiconductor switching device are selectively combined. The circuit network may form a part or an entirety of an integrated circuit.

The passive device may include a semiconductor passive device. The passive device may include either or both of a resistor and a capacitor. The semiconductor rectifying device may include at least one among a pn junction diode, a PIN diode, a Zener diode, a Schottky barrier diode, and a fast recovery diode. The semiconductor switching device may include at least one among a BJT (Bipolar Junction Transistor), an MISFET (Metal Insulator Field Effect Transistor), an IGBT (Insulated Gate Bipolar Junction Transistor) and a JFET (Junction Field Effect Transistor).

With reference to FIG. 4 to FIG. 6 and FIG. 9, the semiconductor device 5 further includes a seal conductor 99 that is embedded inside the first insulating portion 45. The seal conductor 99 is embedded as a wall inside the first insulating portion 45 at an interval from the insulating side walls 49A to 49D in a plan view and demarcates the first insulating portion 45 into the device region 100 and an outer region 101. The seal conductor 99 suppresses penetration of moisture and penetration of cracks into the device region 100 from the outer region 101.

The device region 100 is a region that includes the first functional device 64 (transformer 21), the second functional device 98, the plurality of low potential terminals 67, 68, the plurality of high potential terminals 84, 85, the first low potential wiring 31, the second low potential wiring 32, the first high potential wiring 33, the second high potential wiring 34, etc. The outer region 101 is a region outside the device region 100.

The seal conductor 99 is electrically separated from the device region 100. Specifically, the seal conductor 99 is electrically separated from the first functional device 64 (transformer 21), the second functional device 98, the plurality of low potential terminals 67, 68, the plurality of high potential terminals 84, 85, the first low potential wiring 31, the second low potential wiring 32, the first high potential wiring 33, and the second high potential wiring 34. More specifically, the seal conductor 99 is fixed in an electrically floating state. The seal conductor 99 does not form a current path that is connected to the device region 100.

The seal conductor 99 is formed as a band along the insulating side walls 49A to 49D in a plan view. In this embodiment, the seal conductor 99 is formed in a quadrilateral annular shape (specifically, a square annular shape) in a plan view. The seal conductor 99, thereby, demarcates the device region 100 in a quadrilateral shape (specifically, a square shape) in a plan view. Also, the seal conductor 99 demarcates the outer region 101 of a quadrilateral annular shape (specifically, a square annular shape) that surrounds the device region 100 in a plan view.

Specifically, the seal conductor 99 has an upper end portion at the insulating principal surface 48 side, a lower end portion at the semiconductor chip 40 side, and a wall portion that extends as a wall between the upper end portion and the lower end portion. In this embodiment, the upper end portion of the seal conductor 99 is formed at an interval to the semiconductor chip 40 side from the insulating principal surface 48 and is positioned inside the first insulating portion 45. In this embodiment, the upper end portion of the seal conductor 99 is covered by the uppermost insulating layer 59. The upper end portion of the seal conductor 99 may be covered by one or the plurality of interlayer insulating layers 60. The upper end portion of the seal conductor 99 may be exposed from the uppermost insulating layer 59 instead. The lower end portion of the seal conductor 99 is formed at an interval to the upper end portion side from the semiconductor chip 40.

In this embodiment, the seal conductor 99 is thus embedded inside the first insulating portion 45 so as to be positioned at the semiconductor chip 40 side with respect to the plurality of low potential terminals 67, 68 and the plurality of high potential terminals 84, 85. Also, inside the first insulating portion 45, the seal conductor 99 opposes the first functional device 64 (transformer 21), the first low potential wiring 31, and the second low potential wiring 32 in a direction parallel to the insulating principal surface 48. Inside the first insulating portion 45, the seal conductor 99 may also oppose a part of the second functional device 98 in a direction parallel to the insulating principal surface 48.

The seal conductor 99 includes a plurality of seal plug conductors 102 and one or a plurality (a plurality in this embodiment) of seal via conductors 103. The number of the seal via conductors 103 is arbitrary. The uppermost seal plug conductor 102 among the plurality of seal plug conductors 102 forms the upper end portion of the seal conductor 99. The plurality of seal via conductors 103 each form the lower end portion of the seal conductor 99. The seal plug conductor 102 and the seal via conductor 103 are preferably formed of the same conductive material as the low potential coil 22.

The plurality of seal plug conductors 102 are respectively embedded in the plurality of interlayer insulating layers 60 and are each formed in a quadrilateral annular shape (specifically, a square annular shape) that surrounds the device region 100 in a plan view. The plurality of seal plug conductors 102 are laminated from the lowermost insulating layer 58 toward the uppermost insulating layer 59 so as to be connected to each other. The number of laminated layers of the plurality of seal plug conductors 102 matches the number of laminated layers of the plurality of interlayer insulating layers 60. As a matter of course, one or the plurality of seal plug conductors 102 that penetrate through the plurality of interlayer insulating layers 60 may be formed.

If one annular seal conductor 99 is formed by an assembly of the plurality of seal plug conductors 102, not all of the plurality of seal plug conductors 102 have to be formed in an annular shape. For example, at least one of the plurality of seal plug conductors 102 may be formed in a shape with ends. Also, at least one of the plurality of seal plug conductors 102 may be divided into a plurality of band shaped portions with ends. However, in view of the risk of penetration of moisture and cracks into the device region 100, the plurality of seal plug conductors 102 are preferably formed in an endless shape (annular shape).

The plurality of seal via conductors 103 are each formed in a region between the semiconductor chip 40 and the seal plug conductor 102 in the lowermost insulating layer 58. The plurality of seal via conductors 103 are connected to the semiconductor chip 40 and also connected to the seal plug conductor 102. Thereby, the seal conductor 99 may be fixed at a ground potential by way of a seal via conductor 103. The plurality of seal via conductors 103 have a planar area less than a planar area of the seal plug conductor 102. Where a single seal via conductor 103 is formed, the single seal via conductor 103 may have a planar area equal to or more than a planar area of the seal plug conductor 102.

A width of the seal conductor 99 may be not less than 0.1 μm and not more than 20 μm. The width of the seal conductor 99 is preferably not less than 1 μm and not more than 10 μm. The width of the seal conductor 99 is defined by a width in a direction orthogonal to a direction in which the seal conductor 99 extends.

With reference to FIG. 9, the protective layer 47 is formed on the insulating principal surface 50 of the second insulating portion 46 so as to cover the high potential coil 23 and the plurality of high potential terminals 84, 85. The protective layer 47 may be referred to as a passivation layer. The protective layer 47 protects the second insulating portion 46, the first insulating portion 45 and the semiconductor chip 40 from above the insulating principal surface 50. In this embodiment, the protective layer 47 contains polyimide. A thickness of the protective layer 47 may be not less than 1 μm and not more than 100 μm.

The thickness of the protective layer 47 is preferably not less than a distance D1 between the low potential coil 22 and the high potential coil 23. In this case, the thickness of the protective layer 47 is preferably not less than 5 μm and not more than 100 μm. According to these structures, it is possible to suppress an increase in thickness of the protective layer 47 and also appropriately enhance a dielectric withstand voltage on the high potential coil 23 by the protective layer 47.

As described so far, according to this semiconductor device 5, the first low potential pad 73 and the second low potential pad 74 are separated from the first region 69 with respect to the high potential coil 23 in the first direction X in a plan view. Thereby, as compared with a case that a first low potential pad 73′ and a second low potential pad 74′ (reference) are formed in the first region 69, it is possible to increase a creepage distance between the high potential coil 23 and each of the first low potential pad 73 and the second low potential pad 74. For example, as shown in FIG. 10, distances D_{P1}, D_{P2}, D_{P3} and D_{P4} on a linear line extended from a center of the high potential coil 23 to each of the low potential pads 73, 74, 73′, 74′ are defined as creepage distances. In this case, D_{P1}, a distance between the first low potential pad 73 formed in the second region 70 and the high potential coil 23 and D_{P2}, a distance between the second low potential pad 74 formed in the second region 70 and the high potential coil 23 can be made longer than D_{P3}, a distance between the first low potential pad 73′ formed in the first region 69 and the high potential coil 23 and D_{P4}, a distance between the second low potential pad 74′ formed in the first region 69 and the high potential coil 23.

It is, thereby, possible to suppress occurrence of a creeping discharge in a region between the high potential coil 23 and each of the first low potential pad 73 and the second low potential pad 74. As a result, it is possible to suppress destruction and deterioration of the first insulating portion 45, the second insulating portion 46, and the protective layer 47 between the high potential coil 23 and each of the first low potential pad 73 and the second low potential pad 74. Thus, it is possible to provide the semiconductor device 5 high in reliability.

### Second Preferred Embodiment

FIG. 11 is a schematic plan view of a semiconductor device 5 according to another preferred embodiment of the present disclosure. Hereinafter, a structure corresponding to the structure so far described will be given the same reference numbers, with a description thereof omitted.

In FIG. 4, a pad region 54 is selectively formed at a second corner portion 44B of a semiconductor chip 40 but may be formed as a band along a chip side wall 43D of the semiconductor chip 40, for example, as shown in FIG. 11. Thereby, the pad region 54 includes a pair of second regions 70A, 70B that hold a first region 69 between them along the chip side wall 43D. The second region 70A at one side is formed at a third corner portion 44C of the semiconductor chip 40, and the second region 70B at the other side is formed at the second corner portion 44B of the semiconductor chip 40. A first low potential terminal 67 (first low potential pad 73) and a second low potential terminal 68 (second low potential pad 74) may be respectively formed in the second region 70A at one side and the second region 70B at the other side.

### Third Preferred Embodiment

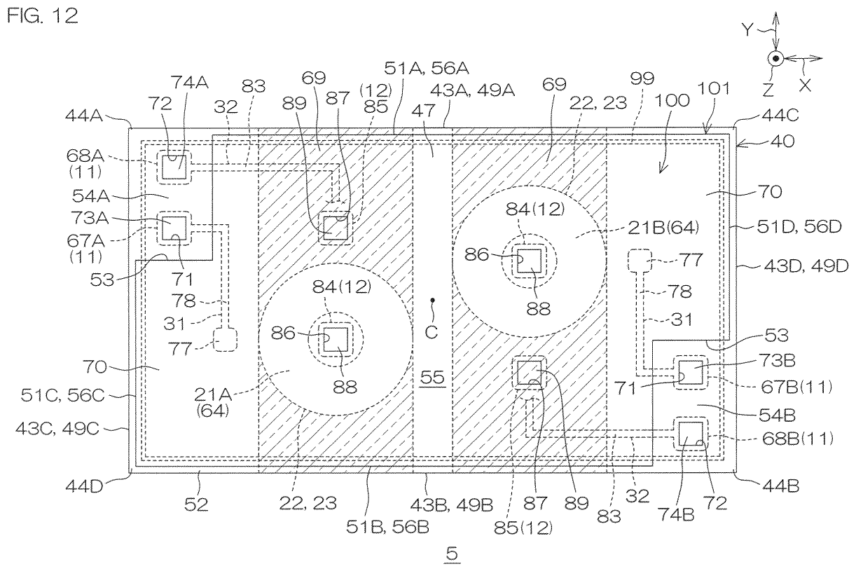

FIG. 12 is a schematic plan view of a semiconductor device 5 according to another preferred embodiment of the present disclosure. Hereinafter, a structure corresponding to the structure so far described will be given the same reference numbers, with a description thereof omitted.

In FIG. 4, one transformer 21 is formed in the semiconductor device 5. However, the plurality of transformers 21 may be formed in the semiconductor device 5. For example, a structure of a pair of transformers 21A, 21B as shown in FIG. 12 may be formed on a common semiconductor chip 40. In this case, the structure of the transformers 21A, 21B may be disposed in a point-symmetrical relationship that the center of gravity of the semiconductor chip 40 in a quadrilateral shape in a plan view is given as a center C. Therefore, a pad region 54A that corresponds to the transformer 21A and a pad region 54B that corresponds to the transformer 21B may be formed at corner portions that are diagonal to each other. In FIG. 12, the pad region 54A is formed at a first corner portion 44A, and the pad region 54B is formed at a second corner portion 44B. That is, first low potential terminals 67A, 67B (first low potential pads 73A, 73B) and second low potential terminals 68A, 68B (second low potential pads 74A, 74B) respectively corresponding to the transformer 21A and the transformer 21B are formed in the pad regions 54A, 54B that are separated from each other.

### Fourth Preferred Embodiment

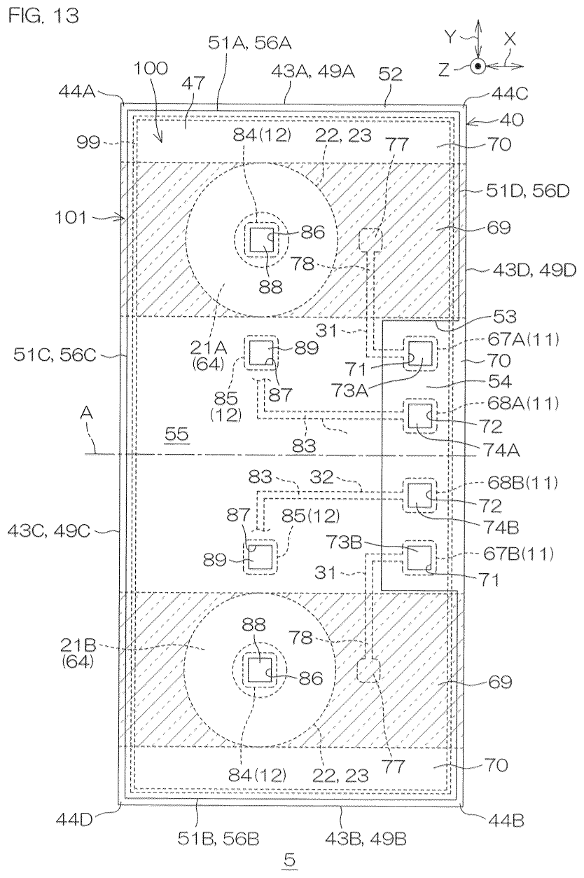

FIG. 13 is a schematic plan view of a semiconductor device 5 according to another preferred embodiment of the present disclosure. Hereinafter, a structure corresponding to the structure so far described will be given the same reference numbers, with a description thereof omitted.

Although a structure of a pair of transformers 21A, 21B may be disposed in a point-symmetrical relationship as shown in FIG. 12, the structure may be disposed in a line-symmetrical relationship that a segment that divides into two parts long sides (third chip side wall 43C and fourth chip side wall 43D in this embodiment) of a semiconductor chip 40 in a quadrilateral shape in a plan view is given as an axis of symmetry A, as shown in FIG. 13.

In this case, the transformer 21A may be formed so as to be close to a first chip side wall 43A of the semiconductor chip 40, and the transformer 21B may be formed so as to be close to a second chip side wall 43B of the semiconductor chip 40. Here, a state that the transformer 21A is formed so as to be close to a first chip side wall 43A may mean that, for example, a state that the transformer 21A is disposed at a side that is close to the first chip side wall 43A with respect to a constitution which is in a relationship of making a pair with the first chip side wall 43A (second chip side wall 43B in this embodiment). This also applies to a case that the transformer 21B is disposed so as to be close to the second chip side wall 43B. Thereby, a relatively large second region 70 is secured between the transformer 21A and the transformer 21B in a second direction Y.

Thus, a pad region 54A that corresponds to the transformer 21A and a pad region 54B that corresponds to the transformer 21B may be formed integrally, and first low potential terminals 67A, 67B (first low potential pads 73A, 73B) and second low potential terminals 68A, 68B (second low potential pads 74A, 74B) that correspond respectively to the transformer 21A and the transformer 21B may be formed in a concentrated manner in a common pad region 54. The pad region 54 is formed so as to be close to at least one of a third chip side wall 43C and a fourth chip side wall 43D (fourth chip side wall 43D in this embodiment) of the semiconductor chip 40.

### Fifth Preferred Embodiment

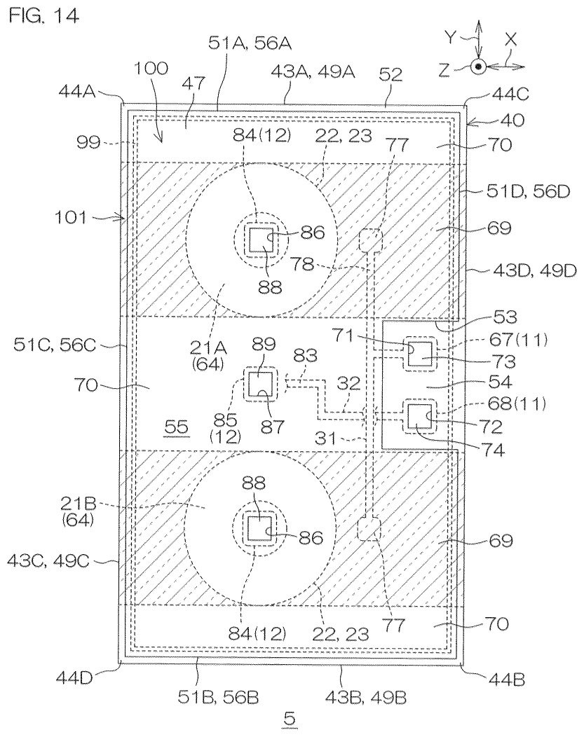

FIG. 14 is a schematic plan view of a semiconductor device 5 according to another preferred embodiment of the present disclosure. Hereinafter, a structure corresponding to the structure so far described will be given the same reference numbers, with a description thereof omitted.

Where the semiconductor device 5 is provided with a structure of a pair of transformers 21A, 21B, a first low potential terminal 67 (first low potential pad 73) and a second low potential terminal 68 (second low potential pad 74) respectively corresponding to the transformers 21A, 21B can be made common, as shown in FIG. 14. That is, the first low potential terminal 67 (first low potential pad 73) and the second low potential terminal 68 (second low potential pad 74) may be connected to both of the pair of transformers 21A, 21B. The pads are made common, by which a pad region 54 can be decreased in area and the semiconductor device 5 can, then, be made into a small chip.

### Sixth Preferred Embodiment

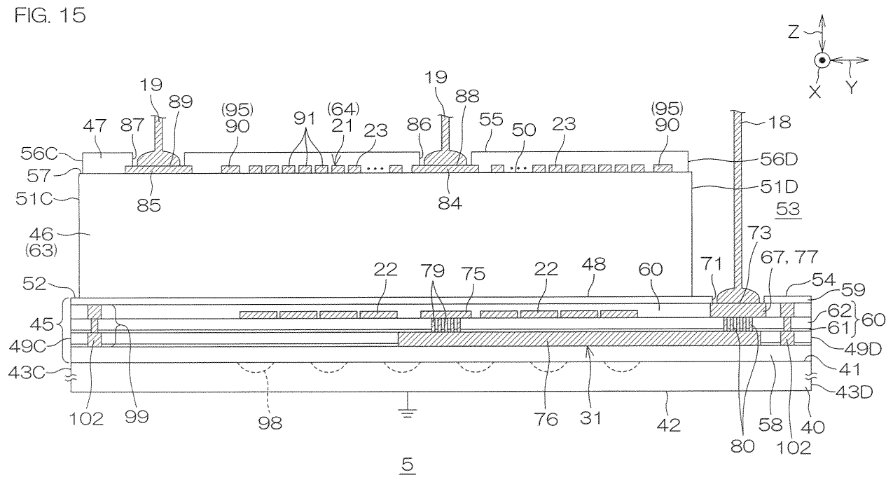

FIG. 15 is a schematic plan view of a semiconductor device 5 according to another preferred embodiment of the present disclosure. Hereinafter, a structure corresponding to the structure so far described will be given the same reference numbers, with a description thereof omitted.

In the previous description, the first low potential wiring 31 and the seal conductor 99 are each connected by way of the substrate plug electrode 81 and the seal via conductor 103 to the semiconductor chip 40 and fixed at a ground potential. On the other hand, as shown in FIG. 15, a substrate plug electrode 81 and a seal via conductor 103 are omitted, by which a first low potential wiring 31 and a seal conductor 99 may not be fixed at a ground potential.

### Seventh Preferred Embodiment

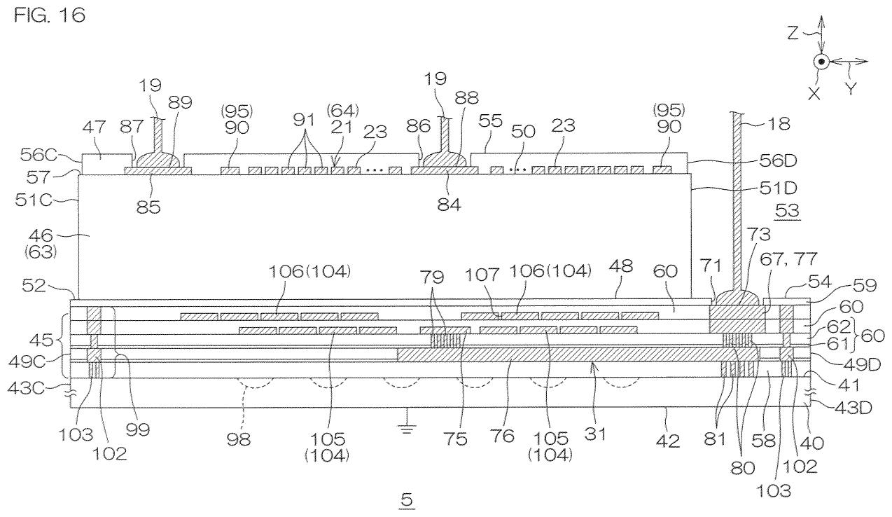

FIG. 16 is a schematic plan view of a semiconductor device 5 according to another preferred embodiment of the present disclosure. Hereinafter, a structure corresponding to the structure so far described will be given the same reference numbers, with a description thereof omitted.

In the previous description, the low potential coil 22 of the transformer 21 is formed inside one interlayer insulating layer 60. However, as shown in FIG. 16, a low potential coil 22 may be a low potential coil 104 that is formed in a plurality of layers of a semiconductor chip 40 in a normal direction Z. For example, the low potential coil 104 may include a first low potential coil 105 that is formed at the semiconductor chip 40 side and a second low potential coil 106 that is formed at a second insulating portion 46 side with respect to the first low potential coil 105.

The first low potential coil 105 and the second low potential coil 106 may be formed inside interlayer insulating layers 60 that are different from each other. For example, of the pair of interlayer insulating layers 60 that are in contact with each other in a normal direction Z, the first low potential coil 105 may be formed in the lower interlayer insulating layer 60 that is close to the semiconductor chip 40, and the second low potential coil 106 may be formed in the upper interlayer insulating layer 60 that is close to the second insulating portion 46.

The first low potential coil 105 and the second low potential coil 106 may be formed so as to be displaced from each other. For example, the first low potential coil 105 may be displaced from the second low potential coil 106 so that the first low potential coil 105 will oppose a gap 107 (region between adjacent spiral portions) of the second low potential coil 106.

### Eighth Preferred Embodiment

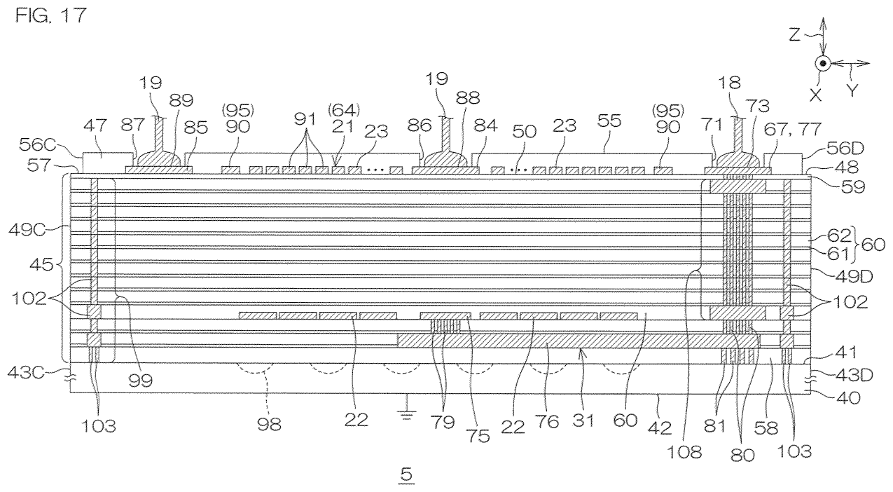

FIG. 17 is a schematic plan view of a semiconductor device 5 according to another preferred embodiment of the present disclosure. Hereinafter, a structure corresponding to the structure so far described will be given the same reference numbers, with a description thereof omitted.

In the previous description, the second insulating portion 46 that is constituted of the organic insulating layer 63 is interposed between the low potential coil 22 and the high potential coil 23. However, a second insulating portion 46 may be omitted. In this case, the number of laminated layers of interlayer insulating layers 60 of a first insulating portion 45 may be adjusted in accordance with a dielectric withstand voltage (dielectric breakdown resistance) to be realized.

Further, low potential terminals 67, 68 may be formed in the same layer (the insulating principal surface 48 of the first insulating portion 45 in this embodiment) as high potential terminals 84, 85. The low potential terminals 67, 68 and a first low potential wiring 31 may be connected by a through wiring 108 which penetrates through the interlayer insulating layer 60 of the first insulating portion 45 in a thickness direction.

### Ninth Preferred Embodiment

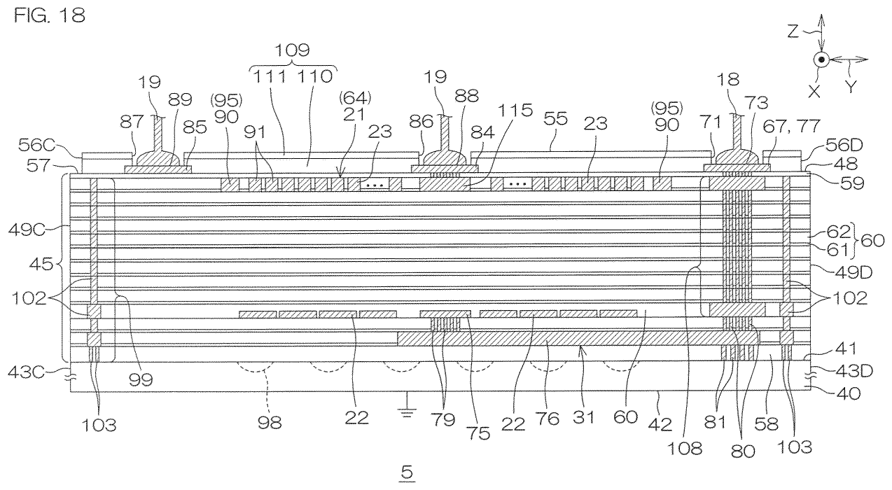

FIG. 18 is a schematic plan view of a semiconductor device 5 according to another preferred embodiment of the present disclosure. Hereinafter, a structure corresponding to the structure so far described will be given the same reference numbers, with a description thereof omitted.

In the previous description, the protective layer 47 is formed of an organic insulating layer. However, as shown in FIG. 18, it may be replaced with a protective layer 109 that is constituted of an inorganic insulating layer. The protective layer 109 has a laminated structure that includes a first inorganic insulating layer 110 and a second inorganic insulating layer 111. The first inorganic insulating layer 110 may contain silicon oxide. The first inorganic insulating layer 110 preferably contains USG (Undoped Silicate Glass) that is impurity-undoped silicon oxide. The second inorganic insulating layer 111 may contain silicon nitride. Where the first inorganic insulating layer 110 is constituted of USG and the second inorganic insulating layer 111 is constituted of silicon nitride, a dielectric breakdown voltage (V/cm) of USG exceeds a dielectric breakdown voltage (V/cm) of silicon nitride. Therefore, where the protective layer 109 is increased in thickness, it is preferable to form the first inorganic insulating layer 110 that is thicker than the second inorganic insulating layer 111.

Further, unlike the case of FIG. 17, the high potential coil 23 may be formed inside a first insulating portion 45. For example, the high potential coil 23 may be embedded in an interlayer insulating layer 60 in contact with an uppermost insulating layer 59. In this case, a first high potential connection portion 115 that connects the high potential coil 23 and a first high potential terminal 84 may be embedded in the interlayer insulating layer 60 in which the high potential coil 23 is formed.

It is noted that FIG. 18 shows a structure in which the semiconductor device 5 described in FIG. 17 is provided with a protective layer 109. Also, in the semiconductor devices 5 of the preferred embodiments other than the ninth preferred embodiment, the protective layer 47 can be replaced with the protective layer 109.

### Tenth Preferred Embodiment

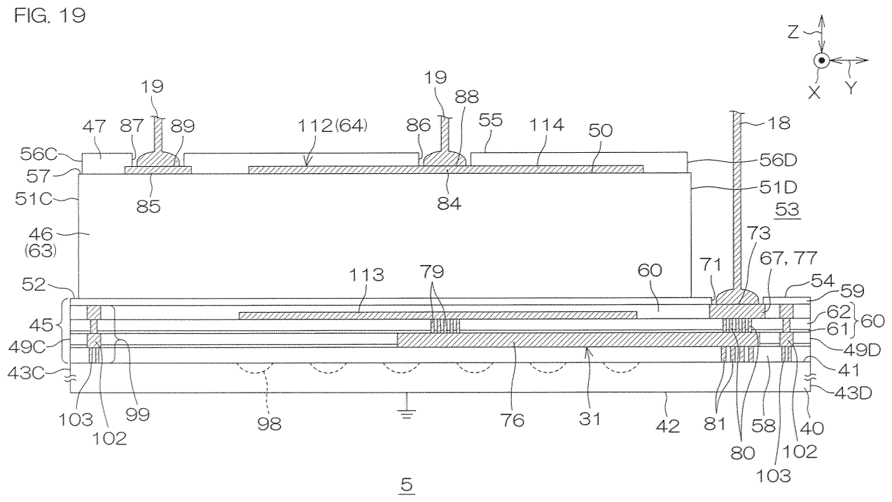

FIG. 19 is a schematic plan view of a semiconductor device 5 according to another preferred embodiment of the present disclosure. Hereinafter, a structure corresponding to the structure so far described will be given the same reference numbers, with a description thereof omitted.

In the previous description, the transformer 21 as an example of the first functional device 64 is installed in the semiconductor device 5. However, as shown in FIG. 19, in place of the transformer 21, a capacitor 112 may be installed. The capacitor 112 may include, for example, a lower electrode 113 that is formed inside a first insulating portion 45 and an upper electrode 114 that is formed on a second insulating portion 46. The lower electrode 113 and the upper electrode 114 may oppose each other across the first insulating portion 45 and the second insulating portion 46.

A description has been so far given of the preferred embodiments of the present disclosure, and the present disclosure can be executed yet in other preferred embodiments.

For example, it is possible to combine the aforementioned features understood from the disclosure of the preferred embodiments above together among preferred embodiments.

In addition, various design modifications can be applied within the scope of matters described in the claims.

The present application corresponds to Japanese Patent Application No. 2020-165411 filed with the Japan Patent Office on Sep. 30, 2020, and the entire disclosure of this application is incorporated herein by reference.

### REFERENCE SIGNS LIST

1 Semiconductor module
2 Package main body
3 Die pad
3A First die pad
3B Second die pad
4 Lead terminal
5 Semiconductor device
6 Controller IC
7 Driver IC
8 Non-mounting surface
9 Mounting surface
10A First side wall
10B Second side wall
10C Third side wall
10D Fourth side wall
11 Low potential terminal
12 High potential terminal
13 First input pad
14 First output pad
15 Second input pad
16 Second output pad
17 First lead wire
18 Second lead wire
19 Third lead wire
20 Fourth lead wire
21 Transformer
21A Transformer
21B Transformer
22 Low potential coil
23 High potential coil
24 First inner terminal end
25 First outer terminal end
26 First spiral portion
27 Second inner terminal end
28 Second outer terminal end
29 Second spiral portion
31 First low potential wiring
32 Second low potential wiring
33 First high potential wiring
34 Second high potential wiring
35 First wiring
36 Second wiring
37 Power supply
38 Reference voltage power supply
39 Power supply
40 Semiconductor chip
41 First principal surface
42 Second principal surface
43A First chip side wall
43B Second chip side wall
43C Third chip side wall
43D Fourth chip side wall
44A First corner portion
44B Second corner portion
44C Third corner portion
44D Fourth corner portion
45 First insulating portion
46 Second insulating portion
47 Protective layer
48 (First insulating portion) insulating principal surface
49A (First insulating portion) first insulating side wall
49B (First insulating portion) second insulating side wall
49C (First insulating portion) third insulating side wall
49D (First insulating portion) fourth insulating side wall
50 (Second insulating portion) insulating principal surface
51A (Second insulating portion) first insulating side wall
51B (Second insulating portion) second insulating side wall
51C (Second insulating portion) third insulating side wall
51D (Second insulating portion) fourth insulating side wall
52 Step
53 Recessed portion
54 Pad region
54A Pad region
54B Pad region
55 Protective principal surface
56A First protective side wall
56B Second protective side wall
56C Third protective side wall
56D Fourth protective side wall
57 Step
58 Lowermost insulating layer
59 Uppermost insulating layer
60 Interlayer insulating layer
61 First insulating layer
62 Second insulating layer
63 Organic insulating layer
64 First functional device
65 First inner region
66 Second inner region
67 First low potential terminal
67A First low potential terminal
67B First low potential terminal
68 Second low potential terminal
68A Second low potential terminal
68B Second low potential terminal
69 First region
70 Second region
70A Second region
70B Second region
71 First pad opening
72 Second pad opening
73 First low potential pad
73A First low potential pad
73B First low potential pad
74 Second low potential pad
74A Second low potential pad
74B Second low potential pad
75 First low potential connection portion
76 First wiring
77 Second low potential connection portion
78 Second wiring
79 First connection plug electrode
80 Second connection plug electrode
81 Substrate plug electrode
82 Third low potential connection portion
83 Third wiring
84 First high potential terminal
85 Second high potential terminal
86 First pad opening
87 Second pad opening
88 First high potential pad
89 Second high potential pad
90 (High potential coil) first portion
91 (High potential coil) second portion
92 First spiral structure
93 Second spiral structure
94 Connection portion
95 Dummy pattern
96 Open portion
97 Connection portion
98 Second functional device
99 Seal conductor
100 Device region
101 Outer region
102 Seal plug conductor
103 Seal via conductor
104 Low potential coil
105 First low potential coil
106 Second low potential coil
107 Gap
108 Through wiring
109 Protective layer
110 First inorganic insulating layer
111 Second inorganic insulating layer
112 Capacitor
113 Lower electrode
114 Upper electrode
115 First high potential connection portion

1. A semiconductor device comprising:
a semiconductor chip that has a principal surface;
a first conductive layer that is formed on the principal surface of the semiconductor chip and connected to a first potential;
a second conductive layer that opposes the first conductive layer of the principal surface in a normal direction and is connected to a second potential higher than the first potential;
an insulating layer that is formed between the first conductive layer and the second conductive layer, and
a first pad that is formed in a region separated from a region that opposes the second conductive layer in a first direction in a plan view when the semiconductor chip is viewed in the normal direction and that is electrically connected to the first conductive layer.

2. The semiconductor device according to claim 1 including
a second pad that is aligned with respect to the second conductive layer in a second direction that intersects the first direction in a plan view, has a width smaller than a width of the second conductive layer in the first direction and is electrically connected to the second conductive layer.

3. The semiconductor device according claim 1, wherein
the semiconductor chip is formed in a quadrilateral shape that has a first corner portion and a second corner portion which are diagonal to each other as well as a third corner portion and a fourth corner portion which are diagonal to each other in a plan view,
the second conductive layer is provided one each such that the second conductive layer is close to the first corner portion, and
the first pad is provided such that the first pad is close to the second corner portion.

4. The semiconductor device according to claim 1, wherein
the semiconductor chip is formed in a quadrilateral shape that has a first side and a second side which oppose each other as well as a third side and a fourth side which oppose each other in a plan view,
the second conductive layer is provided one each in the first side and the second side such that the second conductive layer is close thereto, and
the first pad is provided at least in one of the third side and the fourth side such that the first pad is close thereto in a region between the pair of second conductive layers that oppose each other.

5. The semiconductor device according to claim 1, wherein
the first conductive layer includes a first coil, and
the second conductive layer includes a second coil.

6. The semiconductor device according to claim 5, wherein
the second coil is larger in thickness than the first coil.

7. The semiconductor device according to claim 5, wherein
the second coil has a thickness larger than a pitch of the first coil.

8. The semiconductor device according to claim 5, wherein
the second coil includes a first portion that forms an outermost periphery of the second coil and has a first width and a second portion that forms a coil portion further inside than the first portion and has a second width smaller than the first width.

9. The semiconductor device according to claim 8, wherein
a distance between the first portion and a portion of an outermost periphery of the second portion is larger than a pitch of the second portion.

10. The semiconductor device according to claim 5, wherein
the first coil is AlCu, and
the second coil is Cu.

11. The semiconductor device according to claim 5 including a first conductive member that is connected to an inner end portion of the first coil, extends by crossing the first coil below the first coil and is electrically connected to the first pad.

12. The semiconductor device according to claim 1, wherein
the insulating layer includes an organic insulating layer.

13. The semiconductor device according to claim 12, wherein
the organic insulating layer includes at least one among a polyimide film, a phenol resin film, and an epoxy resin film.

14. The semiconductor device according to claim 1, wherein
the insulating layer includes a laminated structure of a first inorganic insulating layer and a second inorganic insulating layer that is laminated on the first inorganic insulating layer.

15. The semiconductor device according to claim 14, wherein
the first inorganic insulating layer includes a silicon nitride film, and
the second inorganic insulating layer includes a silicon oxide film.

16. A semiconductor module comprising:
a die pad;
the semiconductor device according to claim 5 that is installed on the die pad;
a package main body that seals the die pad and the semiconductor device; and
a lead terminal that is electrically connected to the semiconductor device and exposed from the package main body.

17. The semiconductor module according to claim 16, wherein
the semiconductor device includes a signal-transmitting insulating element for transmitting a signal in an insulation state between the first coil and the second coil, and
the semiconductor module further including a second semiconductor device that is electrically connected to the insulating element.

18. The semiconductor module according to claim 17, wherein
the second semiconductor device includes a control element that is electrically connected to one of the first coil and the second coil, and a driving element that is electrically connected to the other of the first coil and the second coil.
